(19) United States
(12) Patent Application Publication
(10) Pub. No.: US 2025/0143119 A1
(43) Pub. Date: May 1, 2025

(54) DISPLAY DEVICE

(71) Applicant: Samsung Display Co., LTD., Yongin-si (KR)

(72) Inventors: Gana KIM, Yongin-si (KR); Kyungmin KIM, Yongin-si (KR); Byeonghee WON, Yongin-si (KR)

(21) Appl. No.: 18/884,596

(22) Filed: Sep. 13, 2024

(30) Foreign Application Priority Data
Oct. 27, 2023 (KR) 10-2023-0145279

(51) Int. Cl. H10K 59/131; H10K 77/10; H10K 102/00

(52) U.S. Cl. CPC H10K 59/131; H10K 77/111; H10K 2102/311

(57) ABSTRACT

A display device includes a substrate including a first surface and a second surface, which are opposite to each other, where the substrate includes island areas and bridge areas connecting neighboring island areas to each other and having serpentine shapes, and wires arranged on the first surface of the bridge areas, where groove patterns are defined in each of the bridge areas to be opened in a direction of the second surface.

This application claims priority to Korean Patent Application No. 10-2023-0145279, filed on Oct. 27, 2023, and all the benefits accruing therefrom under 35 U.S.C. § 119, the content of which in its entirety is herein incorporated by reference.

### BACKGROUND

### 1. Field

One or more embodiments relate to a display device, and more particularly, to a flexible display device.

### 2. Description of the Related Art

With the development of display devices visually displaying electrical signals, various display devices having desired characteristics such as small thickness, light weight, and low power consumption have been introduced. For example, flexible display devices capable of being folded or rolled have been introduced. Recently, research and development of display devices having various structures, such as stretchable display devices having shapes that may variously change, have been actively conducted.

### SUMMARY

One or more embodiments include a display device, for example, a flexible display device.

Additional aspects will be set forth in part in the description which follows and, in part, will be apparent from the description, or may be learned by practice of the presented embodiments of the disclosure.

According to one or more embodiments, a display device includes a substrate including a first surface and a second surface, which are opposite to each other, where the substrate includes island areas and bridge areas connecting neighboring island areas to each other and having serpentine shapes, and wires arranged on the first surface of the bridge areas, where groove patterns are defined in each of the bridge areas to be opened in a direction of the second surface.

In an embodiment, each of the bridge areas may include two round portions and a straight portion between the two round portions.

In an embodiment, each of the two round portions may include an inner edge and an outer edge, and the groove patterns may be arranged along the inner edge.

In an embodiment, each of the two round portions may include an inner edge and an outer edge, and the groove patterns may be arranged along the outer edge.

In an embodiment, each of the two round portions may include an inner edge and an outer edge, at least one of the groove patterns may be arranged along the inner edge, and a remainder of the groove patterns may be arranged along the outer edge.

In an embodiment, the at least one of the groove patterns arranged along the inner edge and a remainder of the groove patterns arranged along the outer edge may be misaligned with each other.

In an embodiment, each of the bridge area may include a first edge and a second edge, and each of the groove patterns may extend from the first edge of the bridge area to the second edge of the bridge area.

In an embodiment, a width of each of the bridge areas and a width of each of the groove patterns in a direction perpendicular to an extension direction of each of the bridge areas may be the same as each other.

In an embodiment, the groove patterns may be arranged in the two round portions and the straight portion, and an interval between the groove patterns arranged in the two round portions may be smaller than an interval between the groove patterns arranged in the straight portion.

In an embodiment, the groove patterns may be arranged in the two round portions and the straight portion, and a width of each of the groove patterns arranged in the two round portions in an extension direction of each of the bridge areas may be greater than a width of each of the groove patterns arranged in the straight portion in the extension direction of each of the bridge areas.

In an embodiment, the substrate may include a first base layer and a second base layer on the first base layer, and the groove patterns may be defined by an opening defined through the first base layer.

In an embodiment, the substrate may include a first base layer and a second base layer on the first base layer, and the groove patterns may be defined by an opening defined through the first base layer and the second base layer.

In an embodiment, each of the bridge areas may include a first area overlapping the wire and a second area outside the first area, and the groove patterns may be arranged in the second area.

In an embodiment, a width of each of the groove patterns in an extension direction of each of the bridge areas may increase towards an edge of each of the bridge areas.

In an embodiment, a width of each of the groove patterns in an extension direction of each of the bridge areas may decrease towards an edge of each of the bridge areas.

In an embodiment, each of the groove patterns may have a rounded edge along an arc of an imaginary circle or an imaginary oval, in a plan view.

According to one or more embodiments, a display device includes a substrate including a first surface and a second surface, which are opposite to each other, where the substrate includes island areas and bridge areas connecting neighboring island areas to each other and having serpentine shapes, and wires arranged on the first surface of each of the bridge areas, where groove patterns are defined in a portion of the island areas adjacent to the bridge areas and in a portion of the bridge areas adjacent to the island areas to be opened in a direction of the second surface.

In an embodiment, each of the bridge areas may include a first edge and a second edge, and the groove patterns may be arranged along the first edge and an edge of island area connected to the first edge.

In an embodiment, each of the bridge areas may include a first edge and a second edge, at least one of the groove patterns may be arranged along the first edge and an edge of island area connected to the first edge, and a remainder of the groove patterns may be arranged along the second edge and the edge of island area connected to the second edge.

In an embodiment, each of the bridge areas may include a first edge and a second edge, and the groove patterns may be arranged along the first edge and an edge of island area connected to the first edge, where at least one of the groove patterns may extend from the first edge to the second edge or to an edge of the island area connected to the second edge.

According to one or more embodiments, a display device, in which a display area and a non-display area outside the display area are defined, includes a substrate including a first surface and a second surface, which are opposite to each other, where the substrate includes island areas and bridge areas connecting neighboring island areas to each other and having serpentine shapes, and a wire arranged on the first surface of the bridge areas, where groove patterns are defined in the substrate to be opened in a direction of the second surface, and the display area includes a sub-areas having different elongation rates from each other.

In an embodiment, densities of the groove patterns of each of the sub-areas may be different from each other.

In an embodiment, the sub-areas may include a first sub-area, a second sub-area outside the first sub-area, and a third sub-area outside the second sub-area, and a density of the groove patterns of the first sub-area may be greater than a density of the groove patterns of the second sub-area, and the density of the groove pattern of the second sub-area may be greater than a density of the groove patterns of the third sub-area.

In an embodiment, the sub-areas may include a first sub-area, a second sub-area outside the first sub-area, and a third sub-area outside the second sub-area, and a density of the groove patterns of the first sub-area may be less than a density of the groove patterns of the second sub-area, and the density of the groove patterns of the second sub-area may be less than a density of the groove patterns of the third sub-area.

In an embodiment, the sub-areas may include a first sub-area, a second sub-area outside the first sub-area, and a third sub-area outside the second sub-area, and a density of the groove patterns of the second sub-area may be greater than a density of the groove patterns of the first sub-area and a density of the groove patterns of the third sub-area.

Other features of embodiments may become clear from the following drawings, the claims, and the detailed description of the disclosure.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view of a display device according to an embodiment;

FIGS. 2A and 2B are perspective views showing the display device of FIG. 1 stretched in a first direction;

FIG. 2C is a perspective view showing the display device of FIG. 1 stretched in a second direction;

FIG. 2D is a perspective view showing the display device of FIG. 1 stretched in the first direction and the second direction;

FIG. 2E is a perspective view showing the display device of FIG. 1 stretched in a third direction;

FIG. 3 is a plan view schematically showing a display device according to an embodiment;

FIG. 4 is an enlarged plan view of a region IV of FIG. 3 as a portion of a display device, according to an embodiment;

FIG. 5 is a cross-sectional view of a first island portion and a first bridge portion, which are arranged in a display area of a display device, according to an embodiment;

FIGS. 6A to 6C are each an equivalent circuit diagram of a sub-pixel of a display device, according to an embodiment;

FIGS. 7A and 7B are each a cross-sectional view of a light-emitting element of a display device, according to an embodiment;

FIG. 8 is a partial plan view of one first bridge portion included in a display device, according to an embodiment;

FIGS. 9A to 9D are each a cross-sectional view of one first bridge portion included in a display device, according to an embodiment;

FIG. 10A is a partial plan view of one first bridge portion included in a display device, according to an embodiment, and FIG. 10B is a cross-sectional view of the first bridge portion taken along line III-III′ of FIG. 10A;

FIG. 11A is a partial plan view of any one first bridge portion included in a display device, according to an embodiment, and FIG. 11B is a cross-sectional view of the first bridge portion taken along line IV-IV′ of FIG. 11A;

FIG. 12A is a partial plan view of one first bridge portion included in a display device, according to an embodiment, and FIG. 12B is a cross-sectional view of the first bridge portion taken along line V-V′ of FIG. 12A;

FIG. 13A is a partial plan view of one first bridge portion included in a display device, according to an embodiment, and FIG. 13B is a cross-sectional view of the first bridge portion taken along line VI-VI′ of FIG. 13A;

FIG. 14 is a partial plan view of one first bridge portion included in a display device, according to an embodiment;

FIG. 15A is a partial plan view of one first bridge portion included in a display device, according to an embodiment, and FIG. 15B is a cross-sectional view of the first bridge portion taken along line VII-VII′ of FIG. 15A;

FIGS. 16A to 16C are each a plan view of a portion of one first bridge portion included in a display device, according to an embodiment;

FIG. 17A is a plan view of a portion of a display device, according to an embodiment, and FIGS. 17B and 17C are each a cross-sectional view of one first island portion included in a display device, according to an embodiment;

FIGS. 18A and 18B are each a plan view of a portion of a display device, according to an embodiment;

FIGS. 19A to 19C are each a plan view of a display device according to an embodiment;

FIGS. 20A to 20E are each a plan view of a display device according to an embodiment;

FIGS. 21A to 21C are each a plan view of a display device according to an embodiment;

FIGS. 22A and 22B are each a plan view of a display device according to an embodiment; and

FIGS. 23A to 23G are each a perspective view of an example of an electronic device including a display device, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being “formed on” another layer, area, or element, it can be directly or indirectly formed on the other layer, region, or element. That is, for example, intervening layers, regions, or elements may be present.

When a layer, region, component, or the like is connected to another layer, region, component, or the like, the layer, the region, the component, or the like may be directly connected thereto and/or may be indirectly connected thereto with an intervening layer, region, component, or the like therebetween. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the specification, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings, where the same or corresponding elements are denoted by the same reference numerals throughout, and any repetitive detailed description thereof may be omitted or simplified.

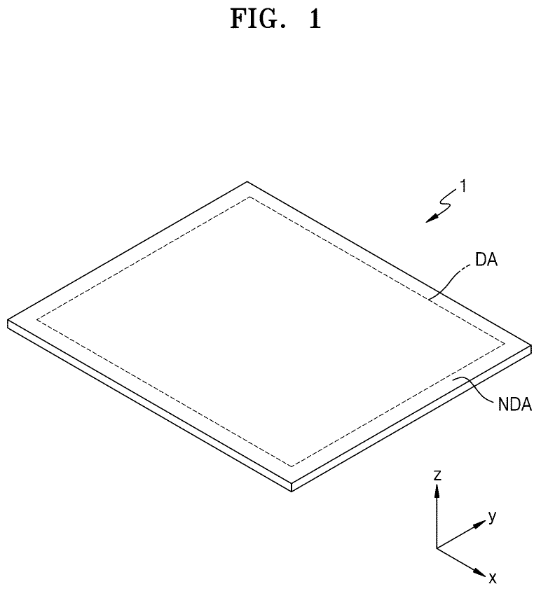

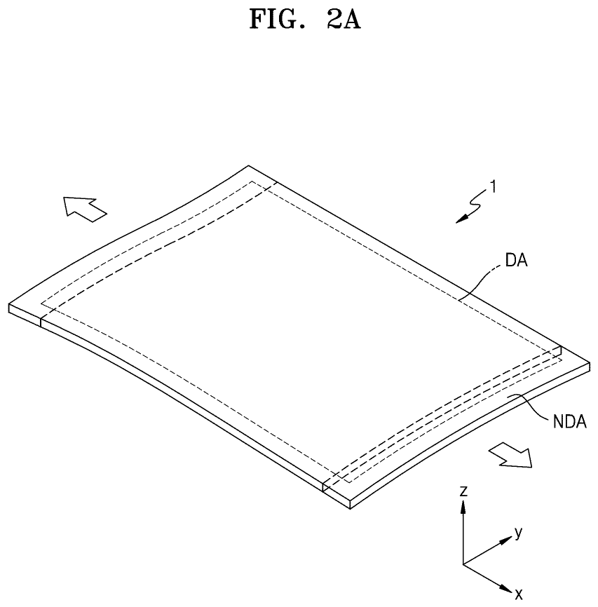

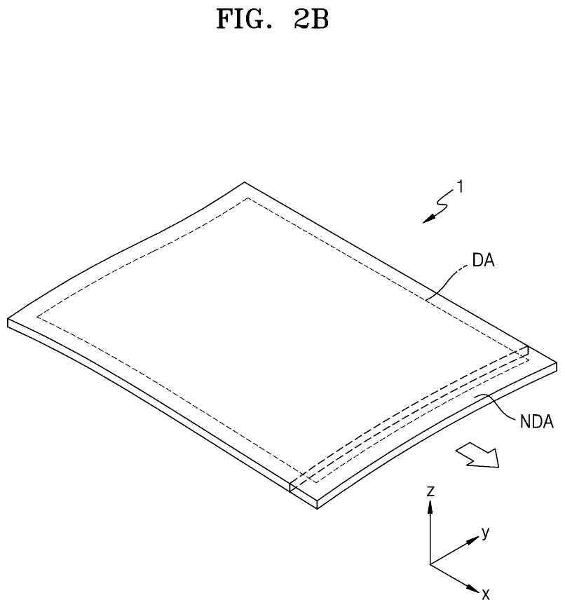

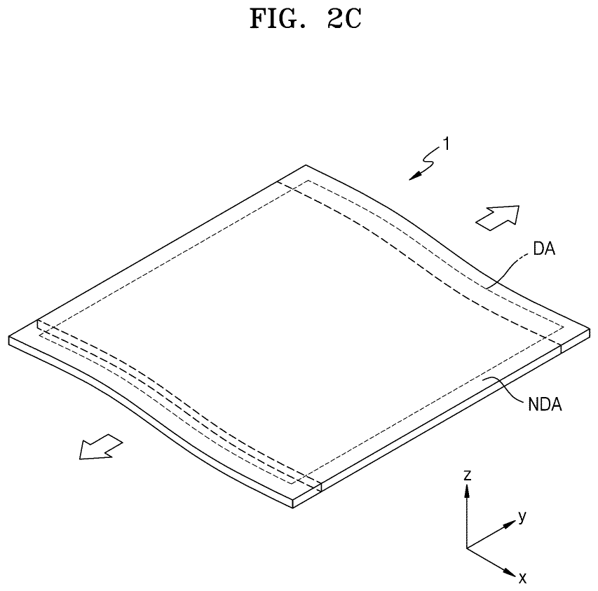

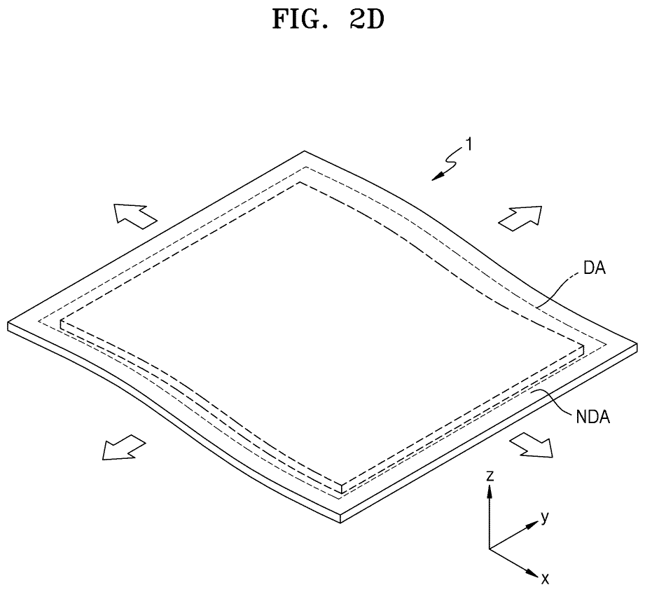

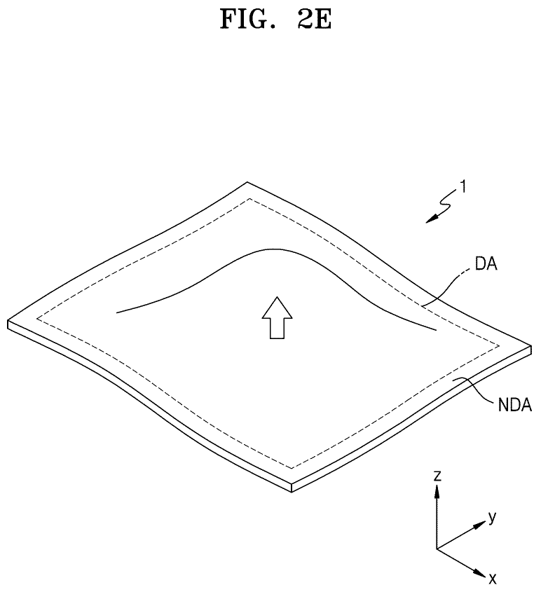

FIG. 1 is a perspective view of a display device 1 according to an embodiment. FIGS. 2A and 2B are perspective views showing the display device 1 of FIG. 1 stretched in a first direction. FIG. 2C is a perspective view showing the display device 1 of FIG. 1 stretched in a second direction. FIG. 2D is a perspective view showing the display device 1 of FIG. 1 stretched in the first direction and the second direction. FIG. 2E is a perspective view showing the display device 1 of FIG. 1 stretched in a third direction.

Referring to FIG. 1, an embodiment of the display device 1 may include a display area DA and a non-display area NDA. The display area DA may include a plurality of pixels. The display device 1 may provide a certain image by using light emitted from the plurality of pixels. The non-display area NDA may be arranged outside the display area DA. The non-display area NDA is an area where pixels are not arranged, and may entirely surround the display area DA.

The display device 1 may be stretched or decreased (or compressed) in various directions. The display device 1 may be stretched in the first direction (e.g., an x direction and/or a −x direction) by external force applied by an external object or a user. According to an embodiment, as shown in FIGS. 2A and 2B, the display area DA and/or the non-display area NDA of the display device 1 may be stretched in the first direction (e.g., the x direction and/or the −x direction). In an embodiment, for example, the display area DA and/or the non-display area NDA may be stretched along the x direction and the −x direction as shown in FIG. 2A, or along the x direction while one side of the display device 1 is fixed as shown in FIG. 2B.

The display device 1 may be stretched in the second direction (e.g., a y direction and/or a −y direction) by external force applied by an external object or the user. In an embodiment, for example, as shown in FIG. 2C, the display area DA and/or the non-display area NDA of the display device 1 may be stretched in the y direction and the −y direction. According to another embodiment, the display area DA and/or the non-display area NDA may be stretched in the y direction or the −y direction while one side of the display device 1 is fixed.

The display device 1 may be stretched in a plurality of directions, e.g., the first direction (e.g., the x direction and/or the −x direction)) and the second direction (e.g., the y direction and/or the −y direction), by external force applied by an external object or a part of body of a person. In an embodiment, for as shown in FIG. 2D, the display area DA and/or the non-display area NDA of the display device 1 may be stretched in the +x direction and the ty direction.

The display device 1 may be stretched in a third direction (e.g., a z direction or a −z direction) by external force applied by an external object or a part of body of a person. According to an embodiment, FIG. 2E illustrates a portion of the display device 1, for example, a partial area of the display area DA, protruding in the z direction. According to another embodiment, a portion of the display device 1, for example, a partial area of the display area DA, may protrude along the −z direction (or be dented along the z direction).

In FIGS. 2A to 2E, embodiments where the display device 1 is stretched in the first direction, the second direction, and/or the third direction are shown, but the disclosure is not limited thereto. According to another embodiment, the display device 1 may be variously transformed in an atypical shape, for example, may be bent or twisted with two or more axes.

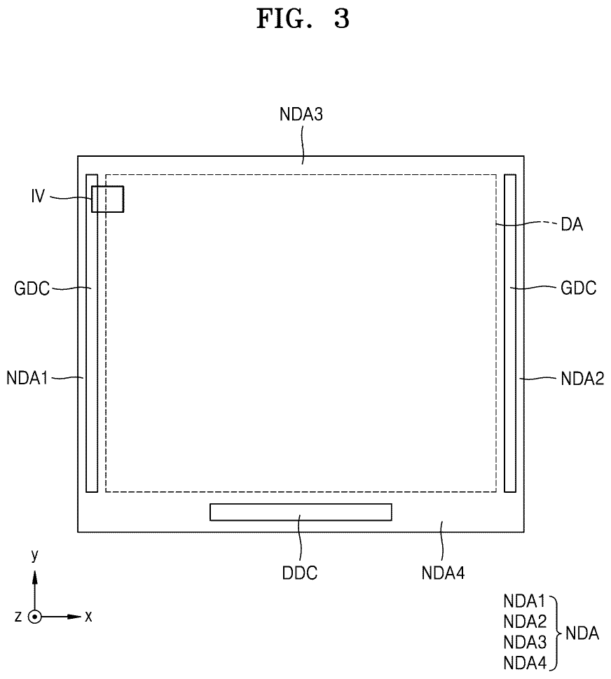

FIG. 3 is a plan view schematically showing the display device 1 according to an embodiment.

In an embodiment of the display device 1, the plurality of pixels may be arranged in the display area DA of the display device 1. Each pixel may include sub-pixels that emit light of different colors. A light-emitting element corresponding to each sub-pixel may be arranged in the display area DA. A circuit configured to provide electrical signals to the light-emitting elements arranged in the display area DA and transistors electrically connected to the light-emitting elements may be located in the non-display area NDA surrounding the display area DA. A gate driving circuit GDC may be arranged in each of a first non-display area NDA1 and a second non-display area NDA2, which are arranged on both opposing sides with the display area DA therebetween. The gate driving circuit GDC may include drivers configured to provide electrical signals to the transistors electrically connected to the light-emitting elements. In an embodiment, as shown in FIG. 3, the gate driving circuit GDC is arranged in each of the first non-display area NDA1 and the second non-display area NDA2, but the disclosure is not limited thereto. According to another embodiment, the gate driving circuit GDC may be arranged in one of the first non-display area NDA1 and the second non-display area NDA2.

A data driving circuit DDC may be arranged in a third non-display area NDA3 and/or a fourth non-display area NDA4, which connect the first non-display area NDA1 and the second non-display area NDA2 to each other. According to an embodiment, as shown in FIG. 3, the data driving circuit DDC may be arranged in the fourth non-display area NDA4. According to another embodiment, the data driving circuit DDC may be arranged in each of the third non-display area NDA3 and the fourth non-display area NDA4.

FIG. 3 illustrates an embodiment where the data driving circuit DDC is arranged in the fourth non-display area NDA4 of the display device 1, but the disclosure is not limited thereto. According to another embodiment, the display device 1 further include a flexible circuit board (not shown) electrically connected through a terminal portion (not shown) arranged in the fourth non-display area NDA4, and the data driving circuit DDC may be disposed on the flexible circuit board.

According to some embodiments, an elongation rate of the non-display area NDA may be equal to or lower than an elongation rate of the display area DA. According to an embodiment, the elongation rate of the non-display area NDA may be different according to areas. In an embodiment, for example, the first non-display area NDA1, the second non-display area NDA2, and the third non-display area NDA3 may have substantially a same elongation rate, but an elongation rate of the fourth non-display area NDA4 may be lower than the elongation rate of each of the first non-display area NDA1, the second non-display area NDA2, and the third non-display area NDA3.

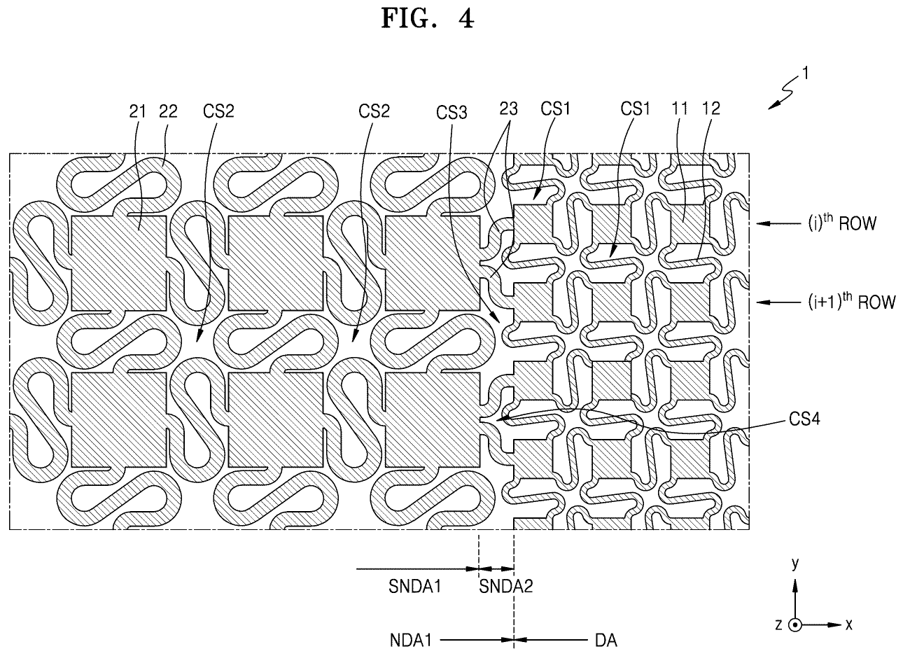

FIG. 4 is an enlarged plan view of a region IV of FIG. 3 as a portion of the display device 1, according to an embodiment.

Referring to FIG. 4, an embodiment of the display device 1 may include first island portions 11 that are spaced apart from each other in the first direction (e.g., the x direction or the −x direction) and the second direction (e.g., the y direction or the −y direction) in the display area DA, and first bridge portions 12 connecting the adjacent first island portions 11 to each other.

The first bridge portions 12 may be spaced apart from each other by a first opening portion CS1 located between the first bridge portions 12. The first bridge portion 12 may have a serpentine shape. In an embodiment, for example, as shown in FIG. 4, the first bridge portion 12 may have a shape of approximately an alphabet “S” or “S”-like shape.

Each first island portion 11 may be connected to the plurality of first bridge portions 12. In an embodiment, for example, each first island portion 11 may be connected to four first bridge portions 12. Two first bridge portions 12 may be arranged on both opposing sides of the first island portion 11 in the first direction (e.g., the x direction or the −x direction), and the remaining two first bridge portions 12 may be arranged on both opposing sides of the first island portion 11 in the second direction (e.g., the y direction or the −y direction). The four first bridge portions 12 may be connected to four sides of the first island portion 11, respectively. The four first bridge portions 12 may be adjacent to corners of the first island portion 11, respectively.

The display device 1 may include second island portions 21 spaced apart from each other in the first direction (e.g., the x direction or the −x direction) and the second direction (e.g., the y direction or the −y direction) in a non-display area, for example, the first non-display area NDA1 of FIG. 4, and second bridge portions 22 connecting the adjacent second island portions 21 to each other or connected between the adjacent second island portions 21.

The second bridge portions 22 may be spaced apart from each other by a second opening portion CS2 located or defined between the second bridge portions 22. The second bridge portion 22 may have a serpentine shape. In an embodiment, for example, as shown in FIG. 4, the second bridge portion 22 may have a shape of approximately an alphabet “S”. The size and/or the width of the second bridge portion 22 may be different from the size and/or the width of the first bridge portion 12. In an embodiment, for example, the size and/or the width of the second bridge portion 22 may be greater than the size and/or the width of the first bridge portion 12. The radius of curvature of a rounded (or curved) portion of the second bridge portion 22 may be different from the radius of curvature of a rounded portion of the first bridge portion 12. In an embodiment, for example, the radius of curvature of the rounded portion of the second bridge portion 22 may be greater than the radius of curvature of the rounded portion of the first bridge portion 12.

Each second island portion 21 may be connected to the plurality of second bridge portions 22. Each second island portion 21 may be connected to the four second bridge portions 22. Two second bridge portions 22 may be arranged on both opposing sides of the second island portion 21 in the first direction (e.g., the x direction or the −x direction), and the remaining two second bridge portions 22 may be arranged on both opposing sides of the second island portion 21 in the second direction (e.g., the y direction or the −y direction). According to an embodiment, the four second bridge portions 22 may be connected to four sides of the second island portion 21, respectively. Each second bridge portion 22 may be connected to a center portion of each side of the second island portion 21.

The second island portions 21 of one row arranged in the first non-display area NDA1 may correspond to the first island portions 11 of a plurality of rows arranged in the display area DA. In an embodiment, for example, the second island portions 21 of one row arranged in the first non-display area NDA1 may correspond to the first island portions 11 arranged in an (i)th row and the first island portions 11 arranged in an (i+1)^{th} row of the display area DA, where i is a positive number greater than 1. According to another embodiment, the second island portions 21 of one row may correspond to n rows of the first island portions 11, where n is a positive number of 3 or greater.

The non-display area, for example, the first non-display area NDA1, may include a first sub-non-display area SNDA1 where the second island portions 21 and the second bridge portions 22 described above are arranged, and a second sub-non-display area SNDA2 between the first sub-non-display area SNDA1 and the display area DA. Third bridge portions 23 connecting the display area DA and the first sub-non-display area SNDA1 to each other may be arranged in the second sub-non-display area SNDA2. One end portion of the third bridge portion 23 may be connected to the second island portion 21 and the other end portion of the third bridge portion 23 may be connected to the first island portion 11. In an embodiment, for example, the one end portion of the third bridge portion 23 may be connected to a center portion of one side of the second island portion 21 and the other end portion of the third bridge portion 23 may be connected to a center portion of one side of the first island portion 11.

The third bridge portion 23 may have a serpentine shape. According to an embodiment, a shape of the third bridge portion 23 may be different from a shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and smaller than the width of the second bridge portion 22. A third opening portion CS3 and a fourth opening portion CS4, which have different shapes from each other, may be alternately arranged between the third bridge portions 23 in the second direction (e.g., the y direction or the −y direction).

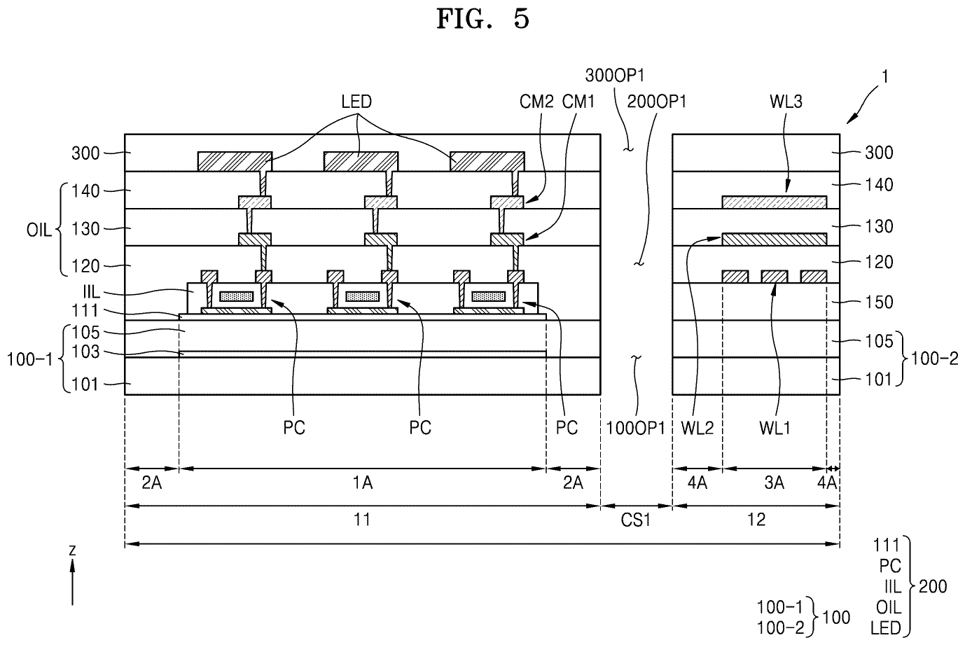

FIG. 5 is a cross-sectional view of the first island portion 11 and the first bridge portion 12, which are arranged in the display area DA of the display device 1, according to an embodiment.

Referring to FIG. 5, in an embodiment, the first island portion 11 and the first bridge portion 12, which are arranged in the display area DA, may be spaced apart from each other with the first opening portion CS1 therebetween. The first island portion 11 may include light-emitting elements LED and a circuit, for example, a pixel driving circuit portion PC, configured to drive the light-emitting elements LED, which is electrically connected thereto, and the first bridge portion 12 may include wires electrically connected to the pixel driving circuit portions PC arranged in the adjacent first island portions 11, respectively.

The display device 1 may include a substrate 100. The substrate 100 may include an island area 100-1 corresponding to the first island portion 11 and a bridge area 100-2 corresponding to the first bridge portion 12.

In an embodiment, the first island portion 11 may include a first area 1A and a second area 2A outside the first area 1A. The first area 1A may be defined as an area where a barrier layer 103, a buffer layer 111, an inorganic insulating layer IIL, and the pixel driving circuit portions PC are arranged. The first area 1A may be located at the center of the first island portion 11 and the width (or the area) of the first area 1A may be less than the width (or the area) of the first island portion 11. In an embodiment, for example, an edge of the first area 1A may be spaced apart from an edge of the first island portion 11, inward. An area from the edge of the first area 1A to the edge of the first island portion 11 may be defined as the second area 2A. The barrier layer 103, the buffer layer 111, the inorganic insulating layer IIL, and the pixel driving circuit portions PC may not overlap the second area 2A.

The island area 100-1 of the substrate 100 may include a first base layer 101, the barrier layer 103, and a second base layer 105. In a plan view (or when viewed in the z direction), the edge of the first island portion 11 may match (or be aligned with) an edge of the island area 100-1.

Each of the first base layer 101 and the second base layer 105 may include a polymer resin, such as polyether sulfone, polyarylate, polyether imide, polyethylene naphthalate, polyethylene terephthalate, polyphenylene sulfide, polyimide, polycarbonate, cellulose triacetate, or cellulose acetate propionate. The substrate 100 including the polymer resin may be flexible, rollable, or bendable.

The barrier layer 103 may be arranged between the first base layer 101 and the barrier layer 103. The barrier layer 103 may include an inorganic insulating material, such as silicon oxide, nitrogen oxide, silicon oxynitride, aluminum oxide, or titanium oxide. The barrier layer 103 may be arranged in the first area 1A. The barrier layer 103 may not overlap the second area 2A.

The buffer layer 111 including an inorganic insulating material may be disposed on a top surface (a surface in the z direction) of the island area 100-1, and the pixel driving circuit portions PC may be disposed on the buffer layer 111. The inorganic insulating layer IIL and an organic insulating layer OIL may be arranged between the pixel driving circuit portion PC and the light-emitting element LED. The inorganic insulating layer IIL may include an inorganic insulating material, such as silicon oxide, nitrogen oxide, silicon oxynitride, aluminum oxide, or titanium oxide. The organic insulating layer OIL may include a first organic insulating layer 120, a second organic insulating layer 130, and a third organic insulating layer 140. Each of the first organic insulating layer 120, the second organic insulating layer 130, and the third organic insulating layer 140 may include an organic insulating material, such as polyimide.

The light-emitting element LED may be disposed on the organic insulating layer OIL and electrically connected to a corresponding pixel driving circuit portion PC through a first connecting electrode CM1 and a second connecting electrode CM2. The first connecting electrode CM1 may be arranged between the first organic insulating layer 120 and the second organic insulating layer 130, and the second connecting electrode CM2 may be arranged between the second organic insulating layer 130 and the third organic insulating layer 140.

The light-emitting elements LED may emit lights of different colors or lights of a same color. According to an embodiment, each of the light-emitting elements LED may emit a red, green, or blue light. According to some embodiments, the light-emitting elements LED may emit a white light. According to another embodiment, each of the light-emitting elements LED may emit a red, green, blue, or white light.

According to an embodiment, as shown in FIG. 5, three pixel driving circuit portions PC may be arranged in each first island portion 11, and three light-emitting elements LED may be connected to corresponding pixel driving circuit portions PC, respectively, but the disclosure is not limited thereto. According to another embodiment, the numbers of pixel driving circuit portions PC and light-emitting elements LED arranged in the first island portion 11 may be one, two, or four or more.

An encapsulation layer 300 may be disposed on the light-emitting element LED and may protect the light-emitting element LED from external force and/or moisture permeability. The encapsulation layer 300 may include an inorganic encapsulation layer and/or an organic encapsulation layer. According to some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked on each other. According to another embodiment, the encapsulation layer 300 may include an organic material such as resin. According to some embodiments, the encapsulation layer 300 may include urethane epoxy acrylate. The encapsulation layer 300 may include a photosensitive material, for example, photoresist.

In an embodiment, the first bridge portion 12 may include a third area 3A and a fourth area 4A outside the third area 3A. The third area 3A may be defined as an area where a first wire portion WL1, a second wire portion WL2, and a third wire portion WL3 are arranged. The width (or the area) of the third area 3A may be less than the width (or the area) of the first bridge portion 12. In an embodiment, for example, an edge of the third area 3A may be spaced apart from an edge of the first bridge portion 12, inwardly. An area from the edge of the third area 3A to the edge of the first bridge portion 12 may be defined as the fourth area 4A. The first wire portion WL1, the second wire portion WL2, and the third wire portion WL3 may not overlap the fourth area 4A.

The bridge area 100-2 of the substrate 100 may include the first base layer 101 and the second base layer 105. In a plan view, the edge of the first bridge portion 12 may match an edge of the bridge area 100-2. The first base layer 101 of the bridge area 100-2 may be a layer formed together during a same process as the first base layer 101 of the island area 100-1. The second base layer 105 of the bridge area 100-2 may be a layer formed together during a same process as the second base layer 105 of the island area 100-1.

The bridge area 100-2 of the substrate 100 may not include the barrier layer 103. The bridge area 100-2 that is relatively transformed further than the island area 100-1 when the display device 1 is stretched may not include a layer including an inorganic insulating material, which is easily cracked, unlike the island area 100-1.

A fourth organic insulating layer 150 may be disposed on a top surface (a surface in the z direction) of the bridge area 100-2. The fourth organic insulating layer 150 may include an organic insulating material, such as polyimide. A top surface of the fourth organic insulating layer 150 may be approximately on a same level as a top surface of the inorganic insulating layer IIL. In other words, a height from a bottom surface of the first base layer 101 to the top surface of the fourth organic insulating layer 150 may be approximately the same as a height from the bottom surface of the first base layer 101 to the top surface of the inorganic insulating layer IIL. The fourth organic insulating layer 150 may reduce a step difference of wires extending from the first island portion 11 to the first bridge portion 12, in the z direction.

The first organic insulating layer 120, the second organic insulating layer 130, and the third organic insulating layer 140 may be sequentially stacked on the fourth organic insulating layer 150. Each of the first organic insulating layer 120, the second organic insulating layer 130, and the third organic insulating layer 140 of the first bridge portion 12 may be a layer formed together during a same process as a corresponding layer of the first island portion 11.

The first wire portion WL1 may be arranged between the fourth organic insulating layer 150 and the first organic insulating layer 120, the second wire portion WL2 may be arranged between the first organic insulating layer 120 and the second organic insulating layer 130, and the third wire portion WL3 may be arranged between the second organic insulating layer 130 and the third organic insulating layer 140.

Each of the first wire portion WL1, the second wire portion WL2, and the third wire portion WL3 may include a low-resistance metal material. Each of the first wire portion WL1, the second wire portion WL2, and the third wire portion WL3 may include a conductive material including molybdenum (Mo), aluminum (AI), copper (Cu), or titanium (Ti), and may be formed in a multilayer or single layer including the conductive material.

Each of the first wire portion WL1, the second wire portion WL2, and the third wire portion WL3 may include at least one wire extending from the first island portion 11 to the first bridge portion 12. In an embodiment, as shown in FIG. 5, the first wire portion WL1 includes three wires, and the second wire portion WL2 and the third wire portion WL3 each include one wire, but the disclosure is not limited thereto. The number and thickness of wires included in each of the first wire portion WL1, the second wire portion WL2, and the third wire portion WL3 may be variously designed according to necessity. The wires included in the first wire portion WL1, the second wire portion WL2, and the third wire portion WL3 may be signal lines (e.g., a gate line, a data line, and the like) configured to provide an electrical signal to a transistor included in the pixel driving circuit portion PC of the first island portion 11, or voltage lines (e.g., a driving voltage line, an initialization voltage line, and the like) configured to provide a voltage.

In an embodiment, the encapsulation layer 300 may also be arranged in the first bridge portion 12. According to another embodiment, the encapsulation layer 300 may not be present in the first bridge portion 12.

Referring to FIGS. 4 and 5, the substrate 100 corresponding to the first island portion 11 and the substrate 100 corresponding to the first bridge portion 12 may be connected to each other. In other words, the plan view shown in FIG. 4 may be substantially the same as the plan view of the substrate 100 of FIG. 5 viewed in the z direction. In other words, the substrate 100 may include the island area 100-1 and the bridge area 100-2, and an opening 100OP1 having a same shape as the first opening portion CS1 may be defined therebetween.

Similarly, the encapsulation layer 300 corresponding to the first island portion 11 and the encapsulation layer 300 corresponding to the first bridge portion 12 may be connected to each other. In an embodiment, for example, the plan view of FIG. 4 may be substantially the same as the plan view of the encapsulation layer 300 of FIG. 5 viewed in the z direction. In other words, the encapsulation layer 300 may include an area corresponding to the first island portion 11 and an area corresponding to the first bridge portion 12, and an opening 300OP1 having a same shape as the first opening portion CS1 may be defined therebetween.

A circuit-light-emitting element layer 200 between the substrate 100 and the encapsulation layer 300 may include the buffer layer 111, the pixel driving circuit portion PC, the inorganic insulating layer IIL, the organic insulating layer OIL, and the light-emitting element LED. Similarly to the substrate 100, the plan view of FIG. 4 may be substantially the same as the plan view of the circuit-light-emitting element layer 200 of FIG. 5 viewed in the z direction. In other words, the circuit-light-emitting element layer 200 may define an opening 200OP1 having a same shape as the first opening portion CS1.

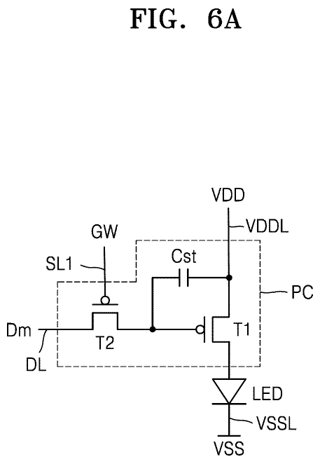

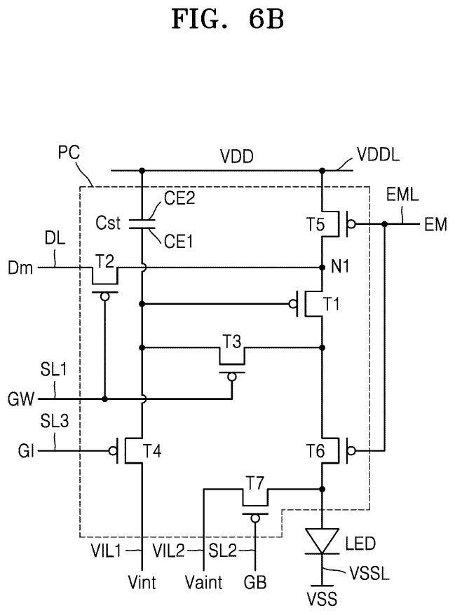

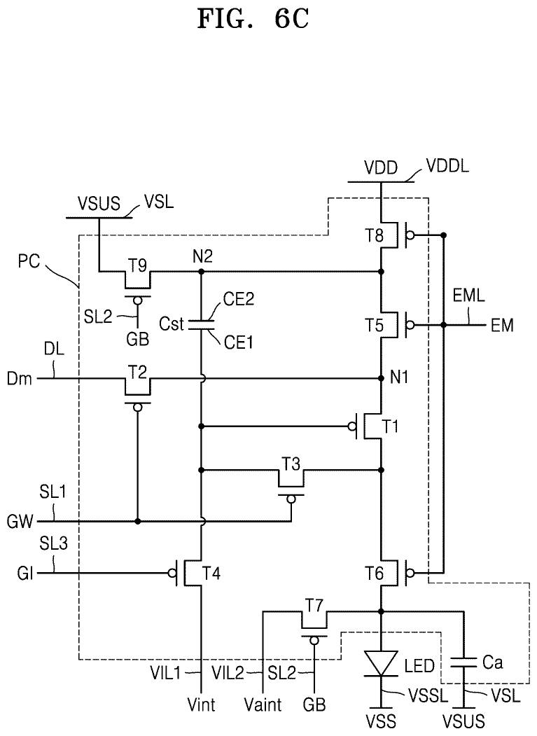

FIGS. 6A to 6C are each an equivalent circuit diagram of a sub-pixel of a display device, according to an embodiment.

Referring to FIG. 6A, in an embodiment, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to transmit, to the first transistor T1, a data signal Dm input from the data line DL, according to the first scan signal GW input from the first scan line SL1.

The storage capacitor Cst may be electrically connected to the second transistor T2 and the first voltage line VDDL, and may be configured to store a voltage corresponding to a difference between a voltage received from the second transistor T2 and a first power voltage VDD supplied by the first voltage line VDDL.

The first transistor T1 is a driving transistor and may be configured to control a driving current flowing through the light-emitting element LED. The first transistor T1 may be connected to the first voltage line VDDL and the storage capacitor Cst. The first transistor T1 may be configured to control the driving current flowing through the light-emitting element LED from the first voltage line VDDL, in response to a value of a voltage stored in the storage capacitor Cst. The light-emitting element LED may be configured to emit a light of a certain luminance according to the driving current. A first electrode of the light-emitting element LED may be electrically connected to the first transistor T1, and a second electrode thereof may be electrically connected to a second voltage line VSSL configured to supply a second power voltage VSS.

In an embodiment, as shown in FIG. 6A, the pixel driving circuit portion PC includes two transistors and one storage capacitor, but according to another embodiment, the pixel driving circuit portion PC may include three or more transistors.

Referring to FIG. 6B, in another embodiment, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include the data line DL and gate lines such as the first scan line SL1, a second scan line SL2, a third scan line SL3 and an emission control line EML. The voltage lines may include a first initialization voltage line VIL1, a second initialization voltage line VIL2, and the first voltage line VDDL.

The first voltage line VDDL may be configured to transmit the first power voltage VDD to the first transistor T1. The first initialization voltage line VIL1 may be configured to transmit, to the pixel driving circuit portion PC, a first initialization voltage Vint for initializing the first transistor T1. The second initialization voltage line VIL2 may be configured to transmit, to the pixel driving circuit portion PC, a second initialization voltage Vaint for initializing the first electrode of the light-emitting element LED.

The first transistor T1 may be electrically connected to the first voltage line VDDL via the fifth transistor T5, and electrically connected to the light-emitting element LED via the sixth transistor T6. The first transistor T1 operates as a driving transistor and is configured to supply a driving current to the light-emitting element LED by receiving the data signal Dm according to a switching operation of the second transistor T2.

The second transistor T2 is a data write transistor and electrically connected to the first scan line SL1 and the data line DL. The second transistor T2 is electrically connected to the first voltage line VDDL via the fifth transistor T5. The second transistor T2 is turned on in response to a first scan signal GW received through the first scan line SL1 to perform a switching operation of transmitting the data signal Dm transmitted to the data line DL, to a first node N1.

The third transistor T3 is electrically connected to the first scan line SL1 and electrically connected to the light-emitting element LED via the sixth transistor T6. The third transistor T3 may be turned on in response to the first scan signal GW received through the first scan line SL1 and diode-connect the first transistor T1.

The fourth transistor T4 is a first initialization transistor and is electrically connected to the third scan line SL3 and the first initialization voltage line VIL1. The fourth transistor T4 may be turned on in response to a third scan signal GI received through the third scan line SL3 to initialize a voltage of the gate electrode of the first transistor T1 by transmitting the first initialization voltage Vint from the first initialization voltage line VIL1 to the gate electrode of the first transistor T1. The third scan signal GI may correspond to a first scan signal from another pixel driving circuit portion arranged in a previous row of the corresponding pixel driving circuit portion PC.

The fifth transistor T5 may be an operation control transistor and the sixth transistor T6 may be an emission control transistor. The fifth transistor T5 and the sixth transistor T6 may be electrically connected to the emission control line EML and simultaneously turned on in response to an emission control signal EM received through the emission control line EML, thereby forming a current path for the driving current to flow in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB received through the second scan line SL2, and may initialize the first electrode of the light-emitting element LED by transmitting the second initialization voltage Vaint from the second initialization voltage line VIL2 to the first electrode of the light-emitting element LED.

The storage capacitor Cst includes a first electrode CE1 and a second electrode CE2. The first electrode CE1 is electrically connected to the gate electrode of the first transistor T1 and the second electrode CE2 is electrically connected to the first voltage line VDDL. The storage capacitor Cst may maintaining a voltage applied to the gate electrode of the first transistor T1 by storing and maintaining a voltage corresponding to a difference between voltages of the first voltage line VDDL and the gate electrode of the first transistor T1.

Referring to FIG. 6C, in another embodiment, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include the data line DL and gate lines such as the first scan line SL1, the second scan line SL2, the third scan line SL3, the fourth scan line SL4, and the emission control line EML. The voltage lines may include the first initialization voltage line VIL1, the second initialization voltage line VIL2, a sustain voltage line VSL, and the first voltage line VDDL.

The first voltage line VDDL may be configured to transmit the first power voltage VDD to the first transistor T1. The first initialization voltage line VIL1 may be configured to transmit, to the pixel driving circuit portion PC, the first initialization voltage Vint for initializing the first transistor T1. The second initialization voltage line VIL2 may be configured to transmit, to the pixel driving circuit portion PC, the second initialization voltage Vaint for initializing the first electrode of the light-emitting element LED. The sustain voltage line VSL may be configured to provide a sustain voltage VSUS to a second node N2, for example, the second electrode CE2 of the storage capacitor Cst, during an initialization period and a data write period.

The first transistor T1 may be electrically connected to the first voltage line VDDL via the fifth transistor T5 and the eighth transistor T8, and electrically connected to the light-emitting element LED via the sixth transistor T6. The first transistor T1 operates as a driving transistor and may be configured to supply the driving current to the light-emitting element LED by receiving the data signal Dm based on a switching operation of the second transistor T2.

The second transistor T2 is electrically connected to the first scan line SL1 and the data line DL, and electrically connected to the first voltage line VDDL via the fifth transistor T5 and the eighth transistor T8. The second transistor T2 is turned on in response to the first scan signal GW received through the first scan line SL1 to perform a switching operation of transmitting the data signal Dm transmitted to the data line DL, to the first node N1.

The third transistor T3 is electrically connected to the first scan line SL1 and electrically connected to the light-emitting element LED via the sixth transistor T6. The third transistor T3 may be turned on in response to the first scan signal GW received through the first scan line SL1 and diode-connect the first transistor T1, thereby compensating for a threshold voltage of the first transistor T1.

The fourth transistor T4 may be connected to the third scan line SL3 and the first initialization voltage line VIL1, and turned on in response to the third scan signal GI received through the third scan line SL3 to transmit the first initialization voltage Vint from the first initialization voltage line VIL1 to the gate electrode of the first transistor T1, thereby initializing a voltage of the gate electrode of the first transistor T1. The third scan signal GI may correspond to a first scan signal from another pixel driving circuit portion arranged in a previous row of the corresponding pixel driving circuit portion PC.

The fifth transistor T5, the sixth transistor T6, and the eighth transistor T8 may be electrically connected to the emission control line EML and simultaneously turned on in response to the emission control signal EM received through the emission control line EML, thereby forming a current path for the driving current to flow in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to the second scan signal GB received through the second scan line SL2, and may initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB received through the second scan line SL2, and configured to transmit the sustain voltage VSUS to the second node N2, for example, second electrode CE2 of the storage capacitor Cst, in the initialization period and the data write period.

The eighth transistor T8 and the ninth transistor T9 may be each electrically connected to the second node N2, for example, the second electrode CE2 of the storage capacitor Cst. According to some embodiments, the eighth transistor T8 may be turned off and the ninth transistor T9 may be turned on in the initialization period and the data write period, and the eighth transistor T8 may be turned on and the ninth transistor T9 may be turned off in an emission period. The sustain voltage VSUS is transmitted to the second node N2 in the initialization period and the data write period, and thus, uniformity (e.g., long range uniformity (LRU)) of luminance of a display device, which may be impaired due to a voltage drop of the first voltage line VDDL, may be enhanced.

The storage capacitor Cst includes the first electrode CE1 and the second electrode CE2. The first electrode CE1 is electrically connected to the gate electrode of the first transistor T1 and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca stores and maintains a voltage corresponding to a voltage difference between the first electrode of the light-emitting element LED and the sustain voltage line VSL while the seventh transistor T7 and the ninth transistor T9 are turned on, thereby effectively preventing an increase in black luminance when the sixth transistor T6 is turned off.

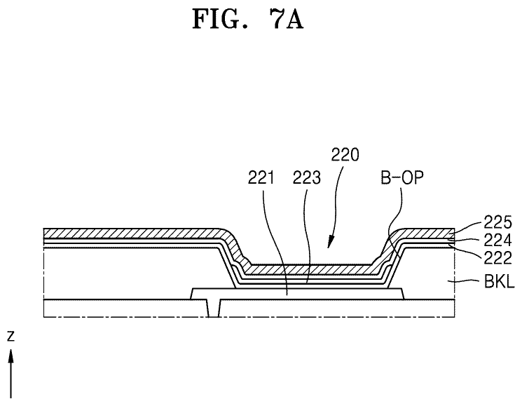

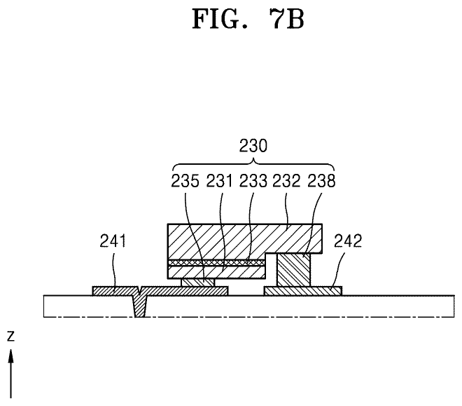

FIGS. 7A and 7B are each a cross-sectional view of a light-emitting element of a display device, according to an embodiment.

Referring to FIG. 7A, the light-emitting element according to an embodiment may include an organic light-emitting diode 220 including an organic material. The organic light-emitting diode 220 may include a first electrode 221 disposed on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered by a bank layer BKL including an insulating material. The bank layer BKL may defined or be provided with an opening B-OP overlapping a center portion of the first electrode 221.

The first electrode 221 may include a conducting oxide, such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to another embodiment, the first electrode 221 may further include a layer including or formed of ITO, IZO, ZnO, or In₂O₃, on/below the reflective layer.

The emission layer 223 may include a high-molecular weight organic material or a low-molecular weight organic material, which emit a light of a certain color. The first functional layer 222 may include a hole transport layer (HTL) and/or a hole injection layer (HIL). The second functional layer 224 may include an electron transport layer (ETL) and/or an electron injection layer (EIL).

A second electrode 225 may include a conductive material with a low work function. In an embodiment, for example, the second electrode 225 may include a (semi-) transparent layer including Ag, Mg, Al, Pt, Pd, Au, Ni, Nd, Ir, Cr, Li, calcium (Ca), or an alloy thereof. Alternatively, the second electrode 225 may further include a layer including ITO, IZO, ZnO, AZO, or In₂O₃, on the (semi-) transparent layer including such a material.

FIG. 7B is a cross-sectional view of a light-emitting element of a display device, according to an embodiment.

Referring to FIG. 7B, the light-emitting element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, which are arranged in (or directly on) a same layer, respectively.

According to some embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and AlInN, and a p-type dopant, such as Mg, Zn, Ca, strontium (Sr), or barium (Ba), may be doped.

The second semiconductor layer 232 may include, for example, an n-type semiconductor layer. The n-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and AlInN, and an n-type dopant, such as Si, Ge, or Sn, may be doped.

The intermediate layer 233 is a region where electrons and holes are recombined, and when the electrons and holes are recombined, the intermediate layer 233 may be transited to a low energy level and generate a light having a corresponding wavelength. The intermediate layer 233 may include, for example, a semiconductor material having a composition formula of InₓAl_{y}Ga_{1-x-y}N (0≤x≤1, 0≤y≤1, 0≤x+y≤1), and may have a single quantum well structure or a multi quantum well (MQW) structure. Also, the intermediate layer may have a quantum wire structure or a quantum dot structure.

In an embodiment, as shown in FIG. 7B, the first semiconductor layer 231 includes the p-type semiconductor layer and the second semiconductor layer 232 includes the n-type semiconductor layer, but the disclosure is not limited thereto. According to another embodiment, the first semiconductor layer 231 may include the n-type semiconductor layer and the second semiconductor layer 232 may include the p-type semiconductor layer.

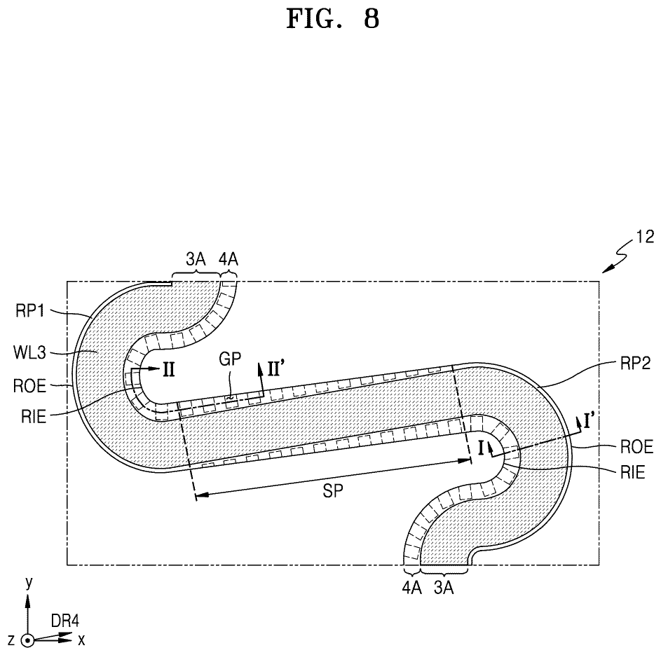

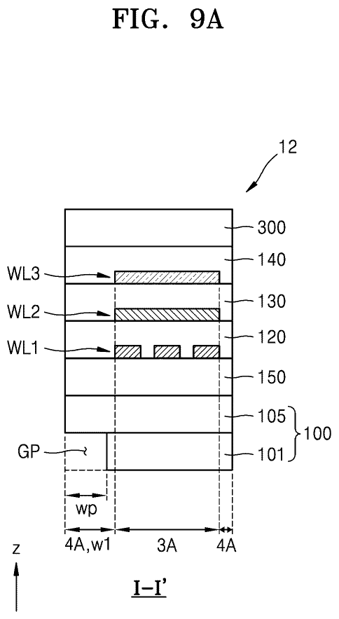

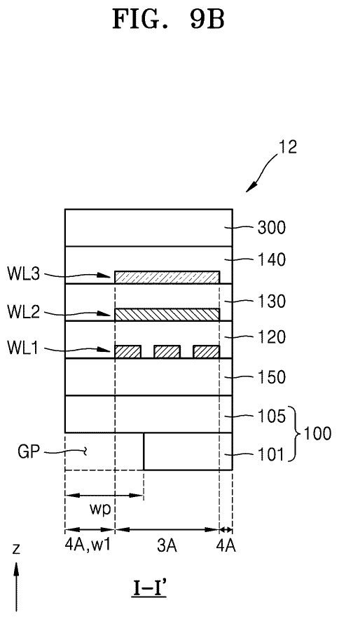

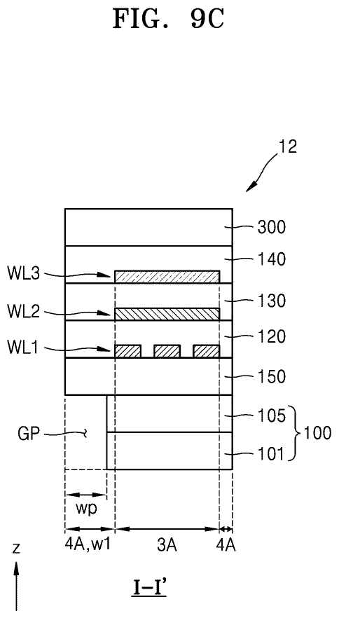

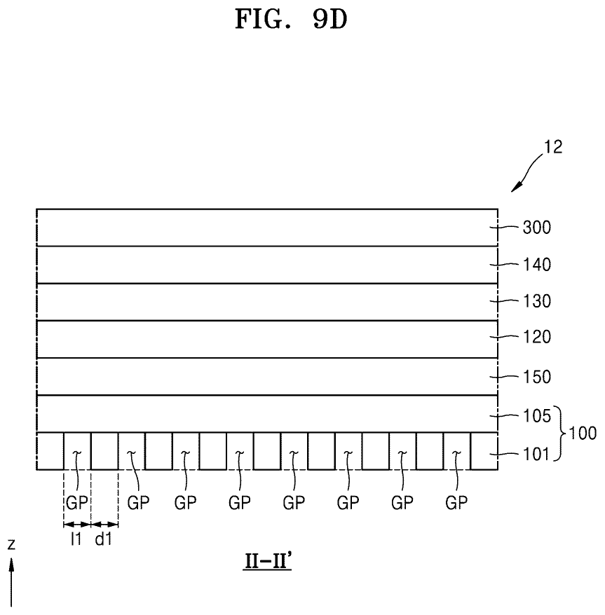

FIG. 8 is a partial plan view of one first bridge portion 12 included in a display device, according to an embodiment, and FIGS. 9A to 9D are each a cross-sectional view of one first bridge portion 12 included in a display device, according to an embodiment. FIGS. 9A to 9C are cross-sectional views of the first bridge portion 12 taken along line I-I′ of FIG. 8, and FIG. 9D is a cross-sectional view of the first bridge portion 12 taken along line II-II′ of FIG. 8.

Referring to FIGS. 8 and 9A to 9D, in an embodiment, the first bridge portion 12 may have a serpentine shape (e.g., an approximately “S” shape). The first bridge portion 12 may be arranged in a gap between two adjacent first island portions 11 (see FIG. 4).

The first bridge portion 12 may include a first round portion RP1, a second round portion RP2, and a straight portion SP between the first round portion RP1 and the second round portion RP2. The width of the first round portion RP1, the width of the second round portion RP2, and the width of the straight portion SP may be substantially the same as each other.

The first round portion RP1 and the second round portion RP2 may have approximately an arc shape and each be connected to an edge of the first island portion 11. The straight portion SP may have an approximately straight shape extending in a fourth direction DR4 oblique to the first direction (e.g., the x direction or the −x direction) and the second direction (e.g., the y direction or the −y direction). One end portion of the straight portion SP may be connected to the first round portion RP1 and the other end portion of the straight portion SP may be connected to the second round portion RP2.

Each of the first round portion RP1 and the second round portion RP2 may have an inner edge RIE and an outer edge ROE. The inner edge RIE may extend along an arc of an imaginary circle having a first radius. The outer edge ROE may extend along an arc of an imaginary circle having a second radius greater than the first radius. One end portion of the inner edge RIE may be connected to an edge of the first island portion 11 and the other end portion of the inner edge RIE may be connected to an edge of the straight portion SP at one side. One end portion of the outer edge ROE may be connected to an edge of the first island portion 11 and the other end portion of the outer edge ROE may be connected to an edge of the straight portion SP at the other side.

The first bridge portion 12 may include the fourth organic insulating layer 150, the first organic insulating layer 120, the second organic insulating layer 130, and the third organic insulating layer 140, which are sequentially stacked on the substrate 100 corresponding to the first bridge portion 12. The first wire portion WL1 may include at least one wire arranged between the fourth organic insulating layer 150 and the first organic insulating layer 120, the second wire portion WL2 may include at least one wire arranged between the first organic insulating layer 120 and the second organic insulating layer 130, and the third wire portion WL3 may include at least one wire arranged between the second organic insulating layer 130 and the third organic insulating layer 140. In an embodiment, as shown in FIGS. 8 to 9A to 9C, the first wire portion WL1 includes three wires, and the second wire portion WL2 and the third wire portion WL3 each include one wire, but the disclosure is not limited thereto. In an embodiment, for example, among the first bridge portions 12, the first bridge portions 12 connecting the first island portions 11 adjacent in the first direction (e.g., the x direction or the −x direction) and the first bridge portions 12 connecting the first island portions 11 adjacent in the second direction (e.g., the y direction or the −y direction) may have wire configurations different from each other.

The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides. In an embodiment, for example, two fourth areas 4A may be arranged with the third area 3A therebetween.

The width (or the area) of the third area 3A may be less than the width (or the area) of the first bridge portion 12. The third area 3A may be arranged closer to the outer edge ROE at the first round portion RP1 and the second round portion RP2. In an embodiment, for example, in a direction perpendicular to an extension direction of the first bridge portion 12, the third area 3A may be spaced apart from the inner edge RIE by a first distance and from the outer edge ROE by a second distance less than the first distance.

When the first bridge portion 12 is contracted or extended by external force, the inner edge RIE of each of the first round portion RP1 and the second round portion RP2 may be stressed more than the outer edge ROE. Accordingly, the third area 3A may be arranged closer to the outer edge ROE at the first round portion RP1 and the second round portion RP2 to reduce or prevent occurrence of a crack in wires of wire portions.

First groove patterns GP opened in the −z direction may be arranged along an edge of the first bridge portion 12 at one side, in the fourth area 4A of the first bridge portion 12. In an embodiment, as shown in FIG. 8, the first groove patterns GP may be arranged along the inner edge RIE of each of the first round portion RP1 and the second round portion RP2 and a portion of an edge extending from the inner edge RIE. Here, the edge extending from the inner edge RIE may denote a portion extending from one end portion of the inner edge RIE and connected to an edge of the first island portion 11 (see FIG. 4), and an edge of the straight portion SP extending from the other end portion of the inner edge RIE. According to an embodiment, the first groove patterns GP may not be arranged in the outer edge ROE of each of the first round portion RP1 and the second round portion RP2. According to an embodiment, the first groove patterns GP may be arranged only in the inner edge RIE of each of the first round portion RP1 and the second round portion RP2.

According to an embodiment, in a plan view, the first groove pattern GP may have a quadrangular shape having one side in contact with the inner edge RIE of the first round portion RP1 or the inner edge RIE of the second round portion RP2. According to another embodiment, in a plan view, the first groove pattern GP may have one of various shapes, such as a polygonal shape, a semicircular shape, and an atypical shape.

The first groove patterns GP may be formed (or defined) on a bottom surface (a surface in the −z direction) of the first bridge portion 12. The bottom surface (the surface in the −z direction) of the first bridge portion 12 is a bottom surface (a surface in the −z direction) of the substrate 100 corresponding to the first bridge portion 12, and thus, the first groove patterns GP may be formed on the bottom surface (the surface in the −z direction) of the substrate 100.

The substrate 100 corresponding to the first bridge portion 12 may have a multilayer structure including the first base layer 101 and the second base layer 105. According to an embodiment, as shown in FIGS. 9A and 9B, the first groove patterns GP may be defined by the first base layer 101. In an embodiment, for example, the first groove patterns GP may be defined by openings defined through the first base layer 101. An edge of the first base layer 101 may have unevenness in zigzags in a plan view (e.g., when viewed in a direction perpendicular to the substrate 100 or the z direction).

According to another embodiment, as shown in FIG. 9C, the first groove patterns GP may be defined by the first base layer 101 and the second base layer 105. In an embodiment, for example, the first groove patterns GP may be defined by openings defined through the first base layer 101 and the second base layer 105. An edge of the first base layer 101 and an edge of the second base layer 105 may overlap in a plan view and have unevenness in zigzags. The first groove patterns GP formed on the substrate 100 corresponding to the first bridge portion 12 may disperse stress concentrated on a portion of the first bridge portion 12 when the first bridge portion 12 is stretched or contracted.

The first groove patterns GP may have a third width wp in a direction perpendicular to an extension direction of the first bridge portion 12. According to an embodiment, as shown in FIGS. 8 and 9A, the third width wp of the first groove pattern GP may be less than or substantially the same as a first width w1 of the corresponding fourth area 4A. In a plan view, the first groove patterns GP may overlap the fourth area 4A and not overlap the third area 3A. According to another embodiment, as shown in FIG. 9B, the third width wp of the first groove pattern GP may be greater than the first width w1 of the corresponding fourth area 4A. In such an embodiment, in a plan view, the first groove patterns GP may overlap the third area 3A and the fourth area 4A at the inner edge RIE.

In an embodiment, as shown in FIG. 9B, the first groove patterns GP are defined by the first base layer 101, but as described with reference to FIG. 9C, the first groove patterns GP may be defined by the first base layer 101 and the second base layer 105. Similarly, the first groove patterns GP according to embodiments described below in the present specification may be defined by the first base layer 101 or by the first base layer 101 and the second base layer 105.

According to an embodiment, as shown in FIGS. 8 and 9D, the first groove patterns GP may have substantially a same width (or a same length) in the extension direction of the first bridge portion 12. The first groove patterns GP may be arranged substantially at a same (or constant) interval. In an embodiment, for example, the first groove patterns GP may each have a first length l1 in the extension direction of the first bridge portion 12 and may be spaced apart from each other in the extension direction of the first bridge portion 12 by a first distance d1.

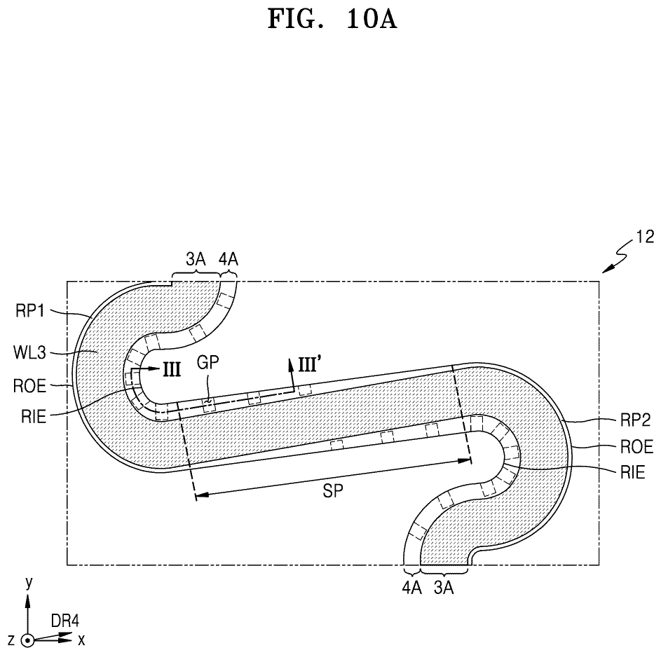

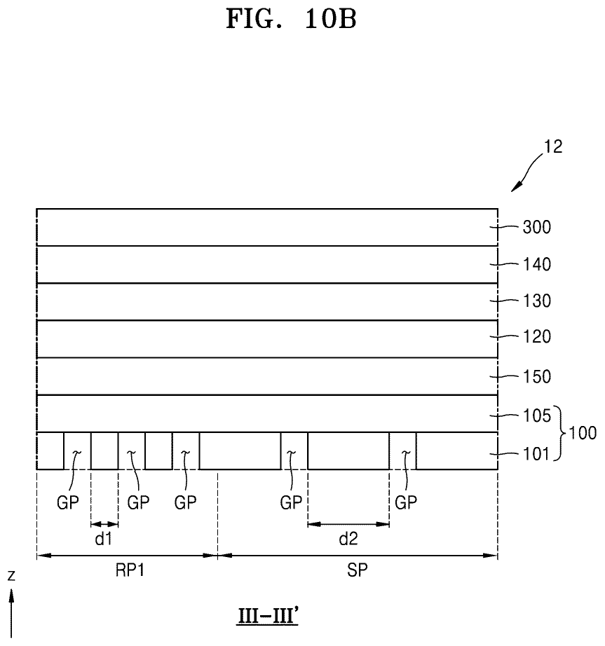

FIG. 10A is a partial plan view of one first bridge portion 12 included in a display device, according to an embodiment, and FIG. 10B is a cross-sectional view of the first bridge portion 12 taken along line III-III′ of FIG. 10A.

Referring to FIGS. 10A and 10B, in an embodiment, the first bridge portion 12 may include the first round portion RP1, the second round portion RP2, and the straight portion SP between the first round portion RP1 and the second round portion RP2. The width of the first round portion RP1, the width of the second round portion RP2, and the width of the straight portion SP may be substantially the same as each other.

The first round portion RP1 and the second round portion RP2 may have approximately an arc shape and each be connected to an edge of the first island portion 11. The straight portion SP may have an approximately straight shape extending in the fourth direction DR4 oblique to the first direction (e.g., the x direction or the −x direction) and the second direction (e.g., the y direction or the −y direction). One end portion of the straight portion SP may be connected to the first round portion RP1 and the other end portion of the straight portion SP may be connected to the second round portion RP2.

Each of the first round portion RP1 and the second round portion RP2 may have the inner edge RIE and the outer edge ROE. The inner edge RIE may extend along the arc of an imaginary circle having the first radius. The outer edge ROE may extend along the arc of an imaginary circle having the second radius greater than the first radius.

The first bridge portion 12 may include the third area 3A and the fourth areas 4A arranged on both opposing sides of the third area 3A. The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides.

The first groove patterns GP opened in the −z direction may be arranged along an edge of the first bridge portion 12 at one side, in the fourth area 4A of the first bridge portion 12. In an embodiment, as shown in FIG. 10A, the first groove patterns GP may be arranged along the inner edge RIE of each of the first round portion RP1 and the second round portion RP2 and a portion of an edge extending from the inner edge RIE. Here, the edge extending from the inner edge RIE may denote a portion extending from one end portion of the inner edge RIE and connected to an edge of the first island portion 11 (see FIG. 4), and portions of an edge of the straight portion SP extending from the other end portion of the inner edge RIE. According to an embodiment, the first groove patterns GP may not be arranged in the outer edge ROE of each of the first round portion RP1 and the second round portion RP2.

The first groove patterns GP may be formed (or defined) on the bottom surface (the surface in the −z direction) of the first bridge portion 12. In other words, the first groove patterns GP may be formed on the bottom surface (the surface in the −z direction) of the substrate 100. The substrate 100 may have a multilayer structure including the first base layer 101 and the second base layer 105. According to an embodiment, as shown in FIG. 10B, the first groove patterns GP may be formed in the first base layer 101. According to another embodiment, the first groove patterns GP may be formed in the first base layer 101 and the second base layer 105.

According to an embodiment, the width of the first groove patterns GP in the direction perpendicular to the extension direction of the first bridge portion 12 may be less than or substantially the same as the width of the corresponding fourth area 4A. In such an embodiment, the first groove patterns GP may overlap the fourth area 4A and not overlap the third area 3A.

According to another embodiment, the width of the first groove patterns GP in the direction perpendicular to the extension direction of the first bridge portion 12 may be greater than the width of the corresponding fourth area 4A. In such an embodiment, the first groove patterns GP may overlap the third area 3A and the fourth area 4A.

The first groove patterns GP may be arranged at different intervals depending on locations. The first groove patterns GP may be arranged more densely in the inner edge RIE of the first round portion RP1 and the inner edge RIE of the second round portion RP2, where stress is concentrated when the first bridge portion 12 is contracted or stretched. According to an embodiment, as shown in FIG. 10B, the neighboring first groove patterns GP in the first round portion RP1 may be spaced apart from each other in the extension direction of the first bridge portion 12 by the first distance d1, and the neighboring first groove patterns GP in the straight portion SP may be spaced apart from each other in the extension direction of the first bridge portion 12 by a second distance d2. Here, the first distance d1 may be smaller than the second distance d2.

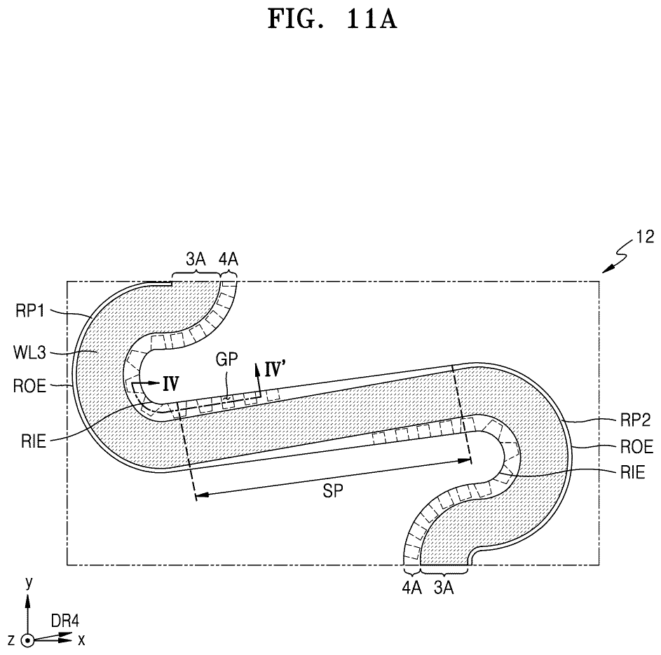

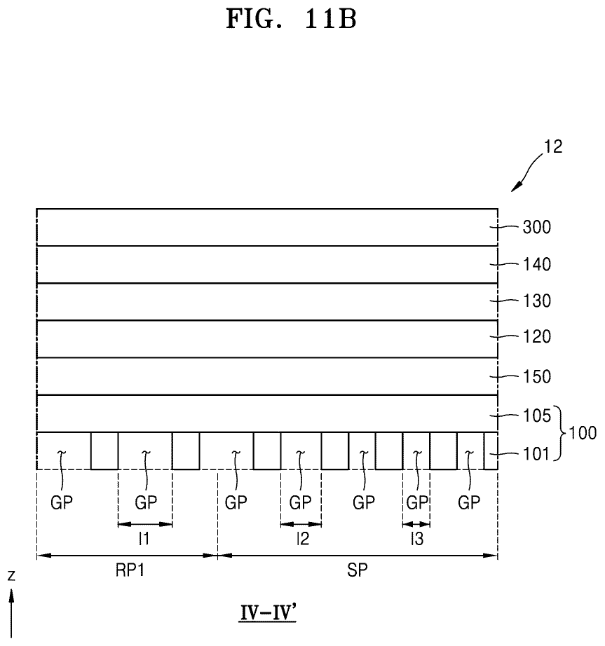

FIG. 11A is a partial plan view of one first bridge portion 12 included in a display device, according to an embodiment, and FIG. 11B is a cross-sectional view of the first bridge portion 12 taken along line IV-IV′ of FIG. 11A.

Referring to FIGS. 11A and 11B, in an embodiment, the first bridge portion 12 may include the first round portion RP1, the second round portion RP2, and the straight portion SP between the first round portion RP1 and the second round portion RP2. Each of the first round portion RP1 and the second round portion RP2 may have the inner edge RIE and the outer edge ROE.

The first bridge portion 12 may include the third area 3A and the fourth areas 4A arranged on both opposing sides of the third area 3A. The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides.

The first groove patterns GP opened in the −z direction may be arranged along an edge of the first bridge portion 12 at one side, in the fourth area 4A of the first bridge portion 12. In an embodiment, as shown in FIG. 11A, the first groove patterns GP may be arranged along the inner edge RIE of each of the first round portion RP1 and the second round portion RP2 and edges of the first bridge portion 12 extending from the inner edge RIE. According to an embodiment, the first groove patterns GP may not be arranged in the outer edge ROE of each of the first round portion RP1 and the second round portion RP2.

The first groove patterns GP may be formed (or defined) on the bottom surface (the surface in the −z direction) of the first bridge portion 12. The first groove patterns GP may be formed on the bottom surface (the surface in the −z direction) of the substrate 100. The substrate 100 may have a multilayer structure including the first base layer 101 and the second base layer 105. According to an embodiment, as shown in FIG. 11B, the first groove patterns GP may be formed in the first base layer 101. According to another embodiment, the first groove patterns GP may be formed in the first base layer 101 and the second base layer 105.

The first groove patterns GP may have different lengths (or widths) in the extension direction of the first bridge portion 12, according to locations. The first groove patterns GP may be longer in the inner edge RIE of the first round portion RP1 and the inner edge RIE of the second round portion RP2, where stress is concentrated when the first bridge portion 12 is contracted or stretched. According to an embodiment, as shown in FIG. 11B, the first groove patterns GP may have the first length l1 in the extension direction of the first bridge portion 12, at the first round portion RP1. The first groove pattern GP may have a second length l2 in the extension direction of the first bridge portion 12, at the straight portion SP. The first length l1 may be greater than the second length l2. According to an embodiment, the length of the first groove pattern GP may decrease away from the first round portion RP1 and the second round portion RP2. In an embodiment, for example, the first groove pattern GP arranged at the straight portion SP and relatively close to the first round portion RP1 may have the second length l2 in the extension direction of the first bridge portion 12. The first groove pattern GP arranged at the straight portion SP and relatively far from the first round portion RP1 may have a third length l3 in the extension direction of the first bridge portion 12. The second length l2 may be greater than the third length l3.

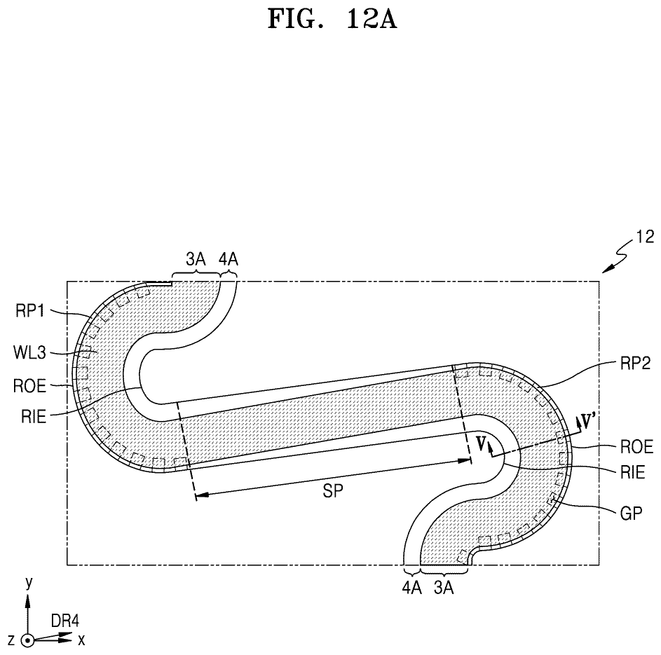

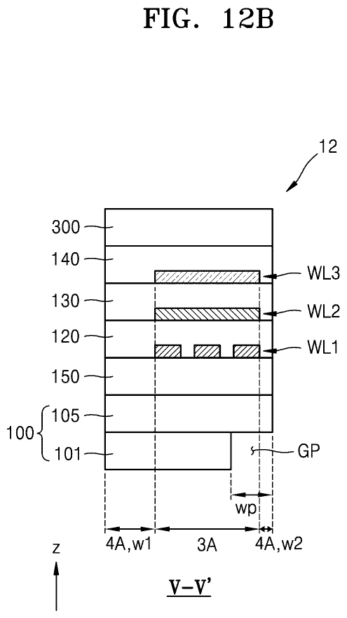

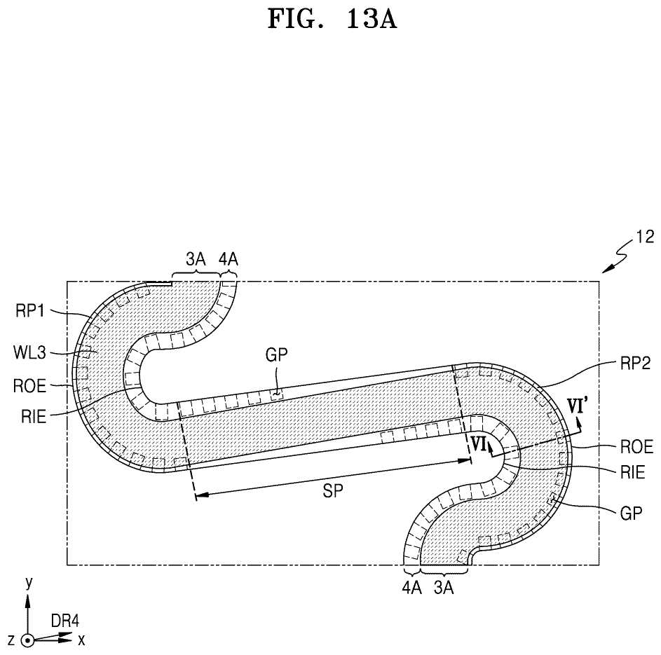

FIG. 12A is a partial plan view of one first bridge portion 12 included in a display device, according to an embodiment, and FIG. 12B is a cross-sectional view of the first bridge portion 12 taken along line V-V′ of FIG. 12A.

Referring to FIGS. 12A and 12B, in an embodiment, the first bridge portion 12 may include the first round portion RP1, the second round portion RP2, and the straight portion SP between the first round portion RP1 and the second round portion RP2. Each of the first round portion RP1 and the second round portion RP2 may have the inner edge RIE and the outer edge ROE.

The first bridge portion 12 may include the third area 3A and the fourth areas 4A arranged on both opposing sides of the third area 3A. The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides.

The first groove patterns GP opened in the −z direction may be arranged along an edge of the first bridge portion 12 at one side, in the fourth area 4A of the first bridge portion 12. In an embodiment, as shown in FIGS. 12A and 12B, the first groove patterns GP may be arranged along the outer edge ROE of each of the first round portion RP1 and the second round portion RP2. According to an embodiment, the first groove patterns GP may not be arranged in the inner edge RIE of each of the first round portion RP1 and the second round portion RP2 and in edges of the straight portion SP.

The first groove patterns GP may be formed (or defined) on the bottom surface (the surface in the −z direction) of the first bridge portion 12. In other words, the first groove patterns GP may be formed on the bottom surface (the surface in the −z direction) of the substrate 100.

The first groove patterns GP may have the third width wp in a direction perpendicular to the extension direction of the first bridge portion 12. According to an embodiment, as shown in FIG. 12B, the third width wp of the first groove pattern GP may be greater than a second width w2 of the overlapping fourth area 4A. In a plan view, the first groove patterns GP may overlap the third area 3A and the fourth area 4A at the outer edge ROE. According to another embodiment, the third width wp of the first groove pattern GP may be less than or substantially the same as the second width w2 of the overlapping fourth area 4A. In such an embodiment, in a plan view, the first groove patterns GP may overlap the fourth area 4A at the outer edge ROE and not overlap the third area 3A.

According to an embodiment, the first groove patterns GP may be spaced apart from each other at substantially a same interval. According to another embodiment, the first groove patterns GP may be arranged at different intervals depending on locations.

According to an embodiment, the first groove patterns GP may have different lengths (or widths) in the extension direction of the first bridge portion 12, according to locations.

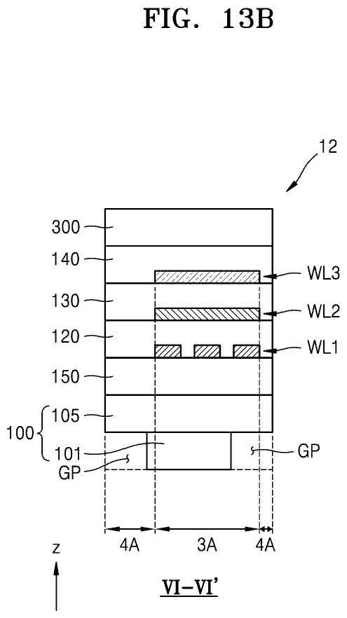

FIG. 13A is a partial plan view of one first bridge portion 12 included in a display device, according to an embodiment, and FIG. 13B is a cross-sectional view of the first bridge portion 12 taken along line VI-VI′ of FIG. 13A.

Referring to FIGS. 13A and 13B, in an embodiment, the first bridge portion 12 may include the first round portion RP1, the second round portion RP2, and the straight portion SP between the first round portion RP1 and the second round portion RP2. Each of the first round portion RP1 and the second round portion RP2 may have the inner edge RIE and the outer edge ROE.

The first bridge portion 12 may include the third area 3A and the fourth areas 4A arranged on both opposing sides of the third area 3A. The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides.

The first groove patterns GP opened in the −z direction may be arranged along edges of the first bridge portion 12 at both opposing sides, in the fourth area 4A of the first bridge portion 12. In an embodiment, as shown in FIGS. 13A and 13B, the first groove patterns GP may be arranged along the inner edge RIE of each of the first round portion RP1 and the second round portion RP2 and the outer edge ROE of each of the first round portion RP1 and the second round portion RP2. The first groove patterns GP may be further arranged along a portion of an edge extending from the inner edge RIE of each of the first round portion RP1 and the second round portion RP2.

The first groove patterns GP may be formed (or defined) on the bottom surface (the surface in the −z direction) of the first bridge portion 12. In other words, the first groove patterns GP may be formed on the bottom surface (the surface in the −z direction) of the substrate 100.

According to an embodiment, the width of the first groove patterns GP in the direction perpendicular to the extension direction of the first bridge portion 12 may be substantially the same as or less than the width of the overlapping fourth area 4A. In such an embodiment, the first groove patterns GP may not overlap the third area 3A. According to another embodiment, the width of the first groove patterns GP in the direction perpendicular to the extension direction of the first bridge portion 12 may be greater than the width of the overlapping fourth area 4A. In such an embodiment, the first groove patterns GP may overlap the third area 3A and the fourth area 4A. According to another embodiment, as shown in FIGS. 13A and 13B, the width of the first groove patterns GP arranged along the inner edge RIE may be substantially the same as or less than the width of the overlapping fourth area 4A, and the width of the first groove patterns GP arranged along the outer edge ROE may be greater than the width of the overlapping fourth area 4A. In such an embodiment, the first groove patterns GP arranged along the inner edge RIE overlap only the fourth area 4A, but the first groove patterns GP arranged along the outer edge ROE may overlap the third area 3A and the fourth area 4A.

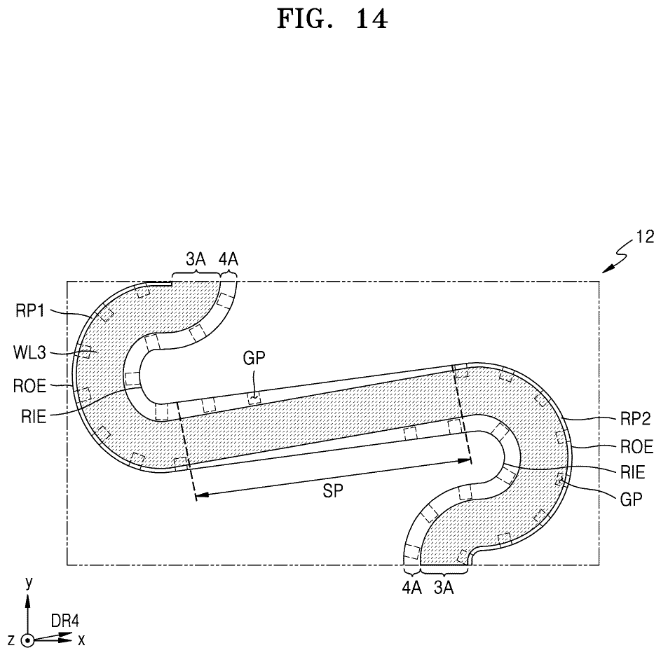

FIG. 14 is a partial plan view of one first bridge portion 12 included in a display device, according to an embodiment.

Referring to FIG. 14, in an embodiment, the first bridge portion 12 may include the first round portion RP1, the second round portion RP2, and the straight portion SP between the first round portion RP1 and the second round portion RP2. Each of the first round portion RP1 and the second round portion RP2 may have the inner edge RIE and the outer edge ROE.

The first bridge portion 12 may include the third area 3A and the fourth areas 4A arranged on both opposing sides of the third area 3A. The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides.

The first groove patterns GP opened in the −z direction and in contact with the edge of the first bridge portion 12 may be arranged in the fourth area 4A of the first bridge portion 12. The first groove patterns GP may be arranged along the inner edge RIE of each of the first round portion RP1 and the second round portion RP2 and the outer edge ROE of each of the first round portion RP1 and the second round portion RP2. The first groove patterns GP may be further arranged along a portion of an edge extending from the inner edge RIE of each of the first round portion RP1 and the second round portion RP2. Here, the first groove patterns GP arranged along the inner edge RIE of each of the first round portion RP1 and the second round portion RP2 and the first groove patterns GP arranged along the outer edge ROE of each of the first round portion RP1 and the second round portion RP2 may be misaligned with each other, i.e., not aligned with each other in a width direction or a direction perpendicular to an extension direction.

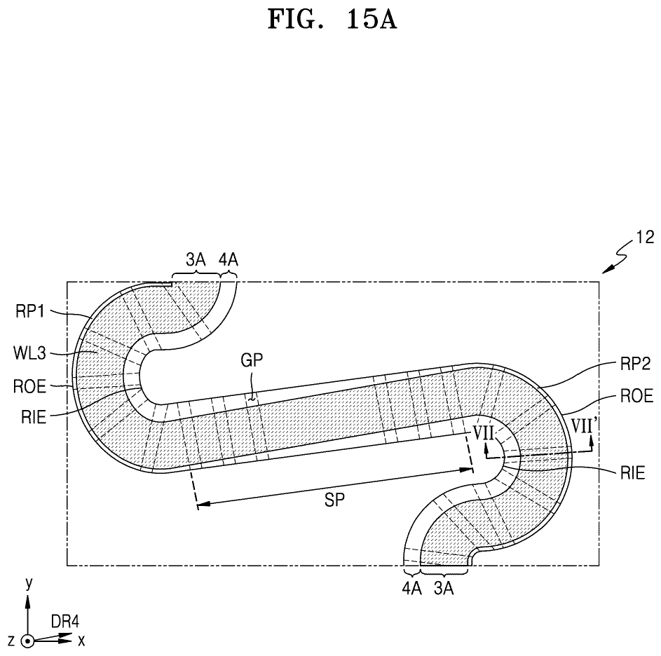

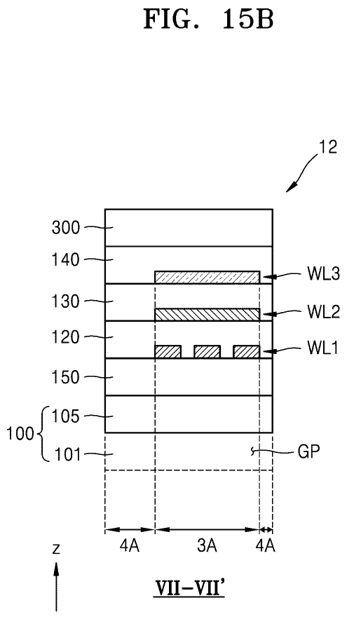

FIG. 15A is a partial plan view of one first bridge portion 12 included in a display device, according to an embodiment, and FIG. 15B is a cross-sectional view of the first bridge portion 12 taken along line VII-VII′ of FIG. 15A.

Referring to FIGS. 15A and 15B, in an embodiment, the first bridge portion 12 may include the first round portion RP1, the second round portion RP2, and the straight portion SP between the first round portion RP1 and the second round portion RP2. Each of the first round portion RP1 and the second round portion RP2 may have the inner edge RIE and the outer edge ROE.

The first bridge portion 12 may include the third area 3A and the fourth areas 4A arranged on both opposing sides of the third area 3A. The third area 3A may be defined as an area where the first wire portion WL1, the second wire portion WL2, and the third wire portion WL3 are arranged, and the fourth areas 4A may be defined as areas between the third area 3A and edges of the first bridge portion 12 at both opposing sides.

The first groove patterns GP opened in the −z direction and in contact with the edges of the first bridge portion 12 at both opposing sides may be arranged in the first bridge portion 12. In other words, the first groove pattern GP may extend from an edge of the first bridge portion 12 at one side to an edge of the first bridge portion 12 at the other side, across the fourth area 4A, the third area 3A, and the fourth area 4A. The width of the first groove patterns GP and the width of the first bridge portion 12 may be the same in the direction perpendicular to the extension direction of the first bridge portion 12.

The substrate 100 corresponding to the first bridge portion 12 may have a multilayer structure including the first base layer 101 and the second base layer 105. According to an embodiment, as shown in FIG. 15B, the first groove patterns GP may be formed only in the first base layer 101. According to another embodiment, the first groove patterns GP may be formed in the first base layer 101 and the second base layer 105.

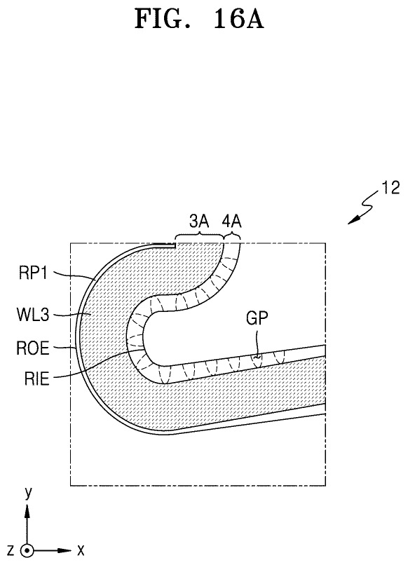

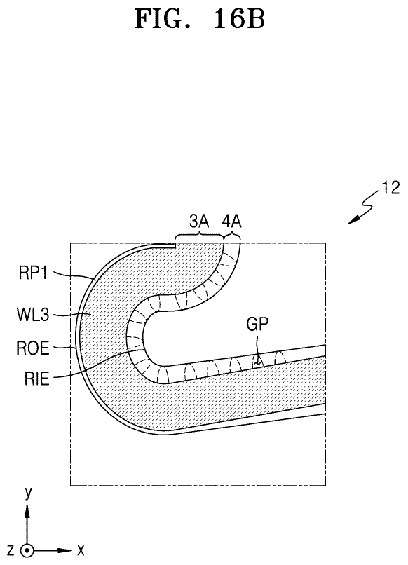

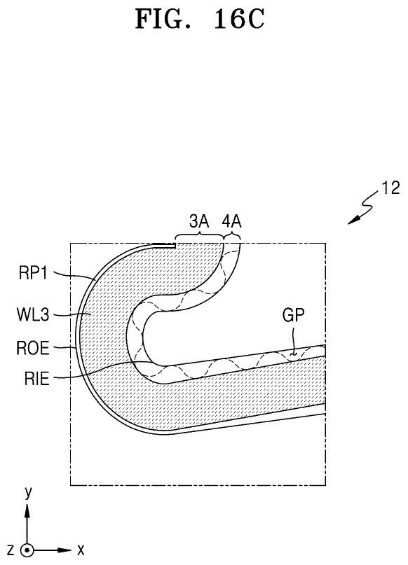

FIGS. 16A to 16C are each a plan view of a portion of one first bridge portion 12 included in a display device, according to an embodiment.

Referring to FIGS. 16A to 16C, in an embodiment, the first groove patterns GP opened in the −z direction and in contact with the edge of the first bridge portion 12 may be arranged in the first bridge portion 12. The first groove patterns GP may be formed (or defined) on the bottom surface (the surface in the −z direction) of the first bridge portion 12. The first groove patterns GP may be formed on the bottom surface (the surface in the −z direction) of the substrate 100 (see FIG. 5) corresponding to the first bridge portion 12.

In a plan view, the first groove pattern GP may have one of various shapes, such as a polygonal shape, a semicircular shape, and an atypical shape. According to an embodiment, as shown in FIG. 16A, the first groove pattern GP may have a shape in which the width (or the length) in the extension direction of the first bridge portion 12 increases towards the edge of the first bridge portion 12. An edge of the first groove pattern GP may have a long axis in the direction perpendicular to the extension direction of the first bridge portion 12, and a center of the first groove pattern GP may be rounded along an arc of an imaginary oval located outside the edge of the first bridge portion 12. The width (or length) of each of the first groove patterns GP in the extension direction of the first bridge portion 12 is increased towards (or increasing as being towards to) the inner edge RIE of the first round portion RP1, and thus, transformation of the first bridge portion 12 may be facilitated. Also, the edge of the first groove pattern GP is rounded, and thus, stability during the transformation of the first bridge portion 12 may be increased.

According to another embodiment, as shown in FIG. 16B, the first groove pattern GP may have a shape in which the width (or the length) in the extension direction of the first bridge portion 12 decreases towards the edge of the first bridge portion 12. The edge of the first groove pattern GP may have the long axis in the direction perpendicular to the extension direction of the first bridge portion 12, and the center of the first groove pattern GP may be rounded along an arc of an imaginary oval located inside the edge of the first bridge portion 12. The width (or length) of each of the first groove patterns GP in the extension direction of the first bridge portion 12 is decreased towards (or decreasing as being towards to) the inner edge RIE of the first round portion RP1, and thus, the first bridge portion 12 may be easily stretched.

According to another embodiment, as shown in FIG. 16C, the first groove pattern GP may have a semi-circular shape in which the length (or the width) in the extension direction of the first bridge portion 12 increases as being towards the edge of the first bridge portion 12. Here, the edges of the neighboring first groove patterns GP may be smoothly connected and have serpentine shapes. In an embodiment, for example, the edges of the first groove patterns GP may be connected to each other to have a shape of approximately an alphabet “S”. In such an embodiment, when the first bridge portion 12 is contracted or stretched, the first bridge portion 12 may be not only transformed in the first direction (e.g., the x direction or the −x direction) and the second direction (e.g., the y direction or the −y direction), but also transformed in the third direction (e.g., the z direction or the −z direction) by the first groove patterns GP, and thus may be twisted.

In an embodiment, as shown in FIGS. 16A to 16C, the first groove patterns GP may be arranged along the inner edge RIE of the first round portion RP1 and the edge extending from the inner edge RIE, but the disclosure is not limited thereto. According to another embodiment, the first groove patterns GP may be arranged along the outer edge ROE of the first round portion RP1. According to another embodiment, the first groove patterns GP may be arranged along the inner edge RIE and outer edge ROE of the first round portion RP1.

In an embodiment, as shown in FIGS. 16A to 16C, the first groove patterns GP overlap the fourth area 4A, but the disclosure is not limited thereto. According to another embodiment, the first groove patterns GP may overlap the third area 3A and the fourth area 4A.

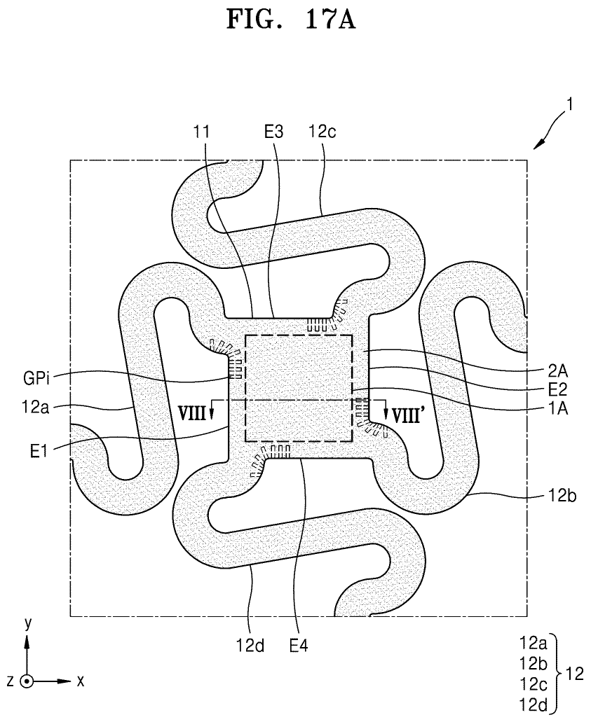

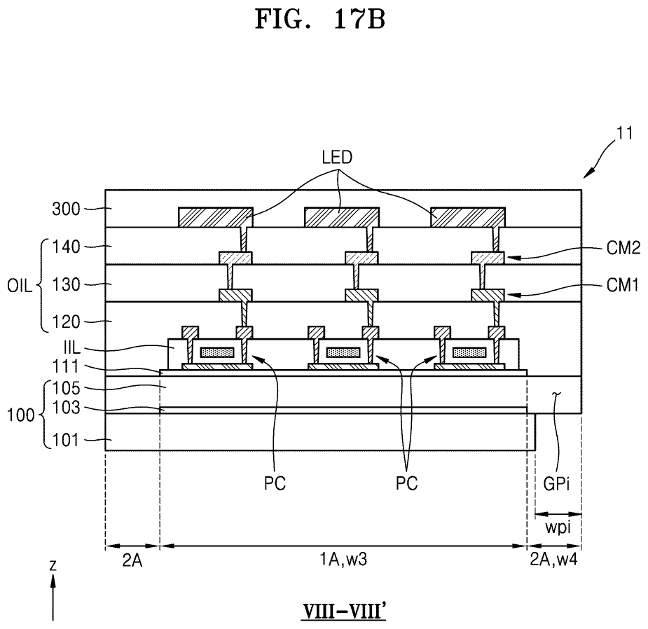

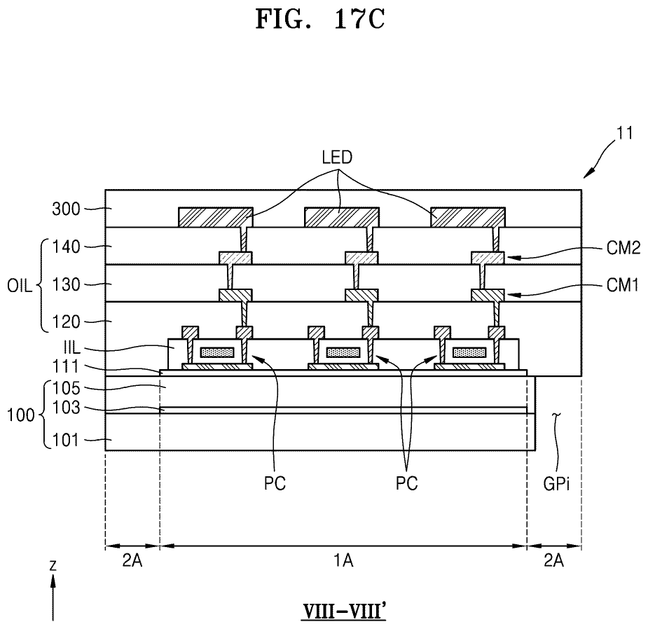

FIG. 17A is a plan view of a portion of the display device 1, according to an embodiment, and FIGS. 17B and 17C are each a cross-sectional view of one first island portion 11 included in the display device 1, according to embodiments.

Referring to FIGS. 17A to 17C, an embodiment of the display device 1 may include the first island portion 11 and the plurality of first bridge portions 12.

The first island portion 11 may have a quadrangular shape having four sides. In an embodiment, for example, the first island portion 11 may include a first edge E1 and a second edge E2, which extend in the second direction (e.g., the y direction or the −y direction), and a third edge E3 and a fourth edge E4, which extend in the first direction (e.g., the x direction or the −x direction) and connecting the first edge E1 and the second edge E2.

The first island portion 11 may be connected to the plurality of first bridge portions 12. The two first bridge portions 12 may be arranged on both opposing sides of the first island portion 11 in the first direction (e.g., the x direction or the −x direction), and the remaining two first bridge portions 12 may be arranged on both opposing sides of the first island portion 11 in the second direction (e.g., the y direction or the −y direction). In an embodiment, for example, the first bridge portions 12 may include a first first bridge portion (hereinafter, will be referred to as “1-1 bridge portion”) 12a, a second first bridge portion (hereinafter, will be referred to as “1-2 bridge portion”) 12b, a third first bridge portion (hereinafter, will be referred to as “1-3 bridge portion”) 12c, and a fourth first bridge portion (hereinafter, will be referred to as “1-4 bridge portion”) 12d. The 1-1 bridge portion 12a may be connected to the first edge E1 of the first island portion 11, the 1-2 bridge portion 12b may be connected to the second edge E2 of the first island portion 11, the 1-3 bridge portion 12c may be connected to the third edge E3 of the first island portion 11, and the 1-4 bridge portion 12d may be connected to the fourth edge E4 of the first island portion 11.

The four first bridge portions 12 may be adjacent to corners of the first island portion 11, respectively. In an embodiment, for example, the 1-1 bridge portion 12a may be adjacent to the corner of the first island portion 11 where the first edge E1 and the third edge E3 meet each other, the 1-2 bridge portion 12b may be adjacent to the corner of the first island portion 11 where the second edge E2 and the fourth edge E4 meet each other, the 1-3 bridge portion 12c may be adjacent to the corner of the first island portion 11 where the second edge E2 and the third edge E3 meet each other, and the 1-4 bridge portion 12d may be adjacent to the corner of the first island portion 11 where the first edge E1 and the fourth edge E4 meet each other.

In an embodiment, the first island portion 11 may include the first area 1A and the second area 2A outside the first area 1A. The first area 1A may be defined as an area where the barrier layer 103, the buffer layer 111, the inorganic insulating layer IIL, and the pixel driving circuit portions PC are arranged. The first area 1A may be located at the center of the first island portion 11 and the width (or the area) of the first area 1A may be less than the width (or the area) of the first island portion 11. In an embodiment, for example, the first area 1A may have a fifth width w3 less than the width of the first island portion 11, and the edge of the first area 1A may be spaced apart from the edge of the first island portion 11 by a fourth width w4, inward.

An area from the edge of the first area 1A to the edge of the first island portion 11 may be defined as the second area 2A. In a plan view, the second area 2A may have a frame shape surrounding the first area 1A. The barrier layer 103, the buffer layer 111, the inorganic insulating layer IIL, and the pixel driving circuit portions PC may not overlap the second area 2A. The second area 2A that is relatively transformed by the first bridge portion 12 further than the first area 1A when the display device 1 is stretched may not include a layer including an inorganic insulating material that is easily cracked, unlike the first area 1A.

Second groove patterns GPi may be arranged in an area where the first island portion 11 and the first bridge portion 12 are connected to each other. Here, the area where the first island portion 11 and the first bridge portion 12 are connected to each other may denote a portion of the first bridge portion 12, adjacent to the first island portion 11, and a portion of the first island portion 11, adjacent to the first bridge portion 12. In other words, the second groove patterns GPi may be arranged in the portion of the first bridge portion 12, adjacent to the first island portion 11, and the portion of the first island portion 11, adjacent to the first bridge portion 12.

According to an embodiment, as shown in FIG. 17A, the second groove patterns GPi may be arranged in each of the areas where the first island portion 11 and the first bridge portion 12 are connected to each other. The second groove patterns GPi may be arranged along the edge of each of the first bridge portions 12 at one side and the edge of the first island portion 11 connected to the edge of each of the first bridge portions 12 at one side.

In an embodiment, for example, where the edges of each of the first bridge portions 12 are referred to as a first edge and a second edge clockwise, the second groove patterns GPi may be arranged along the first edge of the 1-1 bridge portion 12a and the first edge E1 of the first island portion 11, connected to the first edge of the 1-1 bridge portion 12a, in an area where the first island portion 11 and the 1-1 bridge portion 12a are connected to each other. Similarly, the second groove patterns GPi may be arranged along the first edge of the 1-2 bridge portion 12b and the second edge E2 of the first island portion 11, connected to the first edge of the 1-2 bridge portion 12b, in an area where the first island portion 11 and the 1-2 bridge portion 12b are connected to each other. The second groove patterns GPi may be arranged along the first edge of the 1-3 bridge portion 12c and the third edge E3 of the first island portion 11, connected to the first edge of the 1-3 bridge portion 12c, in an area where the first island portion 11 and the 1-3 bridge portion 12c are connected to each other. The second groove patterns GPi may be arranged along the first edge of the 1-4 bridge portion 12d and the fourth edge E4 of the first island portion 11, connected to the first edge of the 1-4 bridge portion 12d, in an area where the first island portion 11 and the 1-4 bridge portion 12d are connected to each other.

The second groove patterns GPi may be formed (or defined) on a bottom surface (a surface in the −z direction) of the first island portion 11 and the bottom surface (the surface in the −z direction) of the first bridge portion 12. The bottom surface (the surface in the −z direction) of the first island portion 11 is the bottom surface (the surface in the −z direction) of the substrate 100 corresponding to the first island portion 11, and the bottom surface (the surface in the −z direction) of the first bridge portion 12 is the bottom surface (the surface in the −z direction) of the substrate 100 corresponding to the first bridge portion 12, and thus, the second groove patterns GPi may be formed on the bottom surface (the surface in the −z direction) of the substrate 100.

The substrate 100 corresponding to the first island portion 11 may include the first base layer 101, the barrier layer 103, and the second base layer 105. According to an embodiment, as shown in FIG. 17B, the second groove pattern GPi may be defined by the first base layer 101. In an embodiment, for example, the second groove pattern GPi may be defined by an opening defined through the first base layer 101. According to another embodiment, as shown in FIG. 17C, the second groove pattern GPi may be defined by the first base layer 101 and the second base layer 105. For example, the second groove pattern GPi may be defined by an opening defined through the first base layer 101 and the second base layer 105.

The second groove pattern GPi may have a sixth width wpi inward from the edge of the first island portion 11. According to an embodiment, the sixth width wpi may be less than the fourth width w4. Accordingly, the second groove patterns GPi arranged in the first island portion 11 may not overlap the first area 1A and may overlap the second area 2A.

Among the second groove patterns GPi, the second groove patterns GPi arranged in the first bridge portion 12 may be portions of the first groove pattern GP described above.

The second groove patterns GPi may reduce or prevent stress concentrated on an area where the edge of the first island portion 11 and the edge of the first bridge portion 12 are connected to each other when the display device 1 is contracted or stretched.

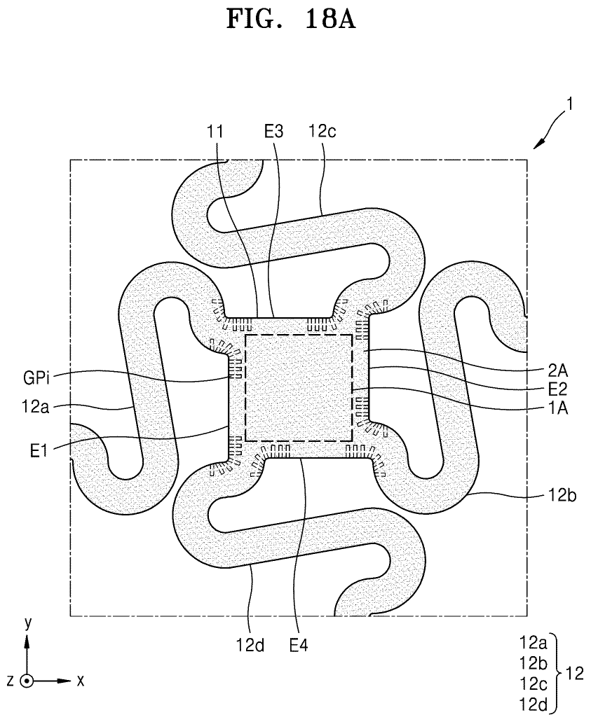

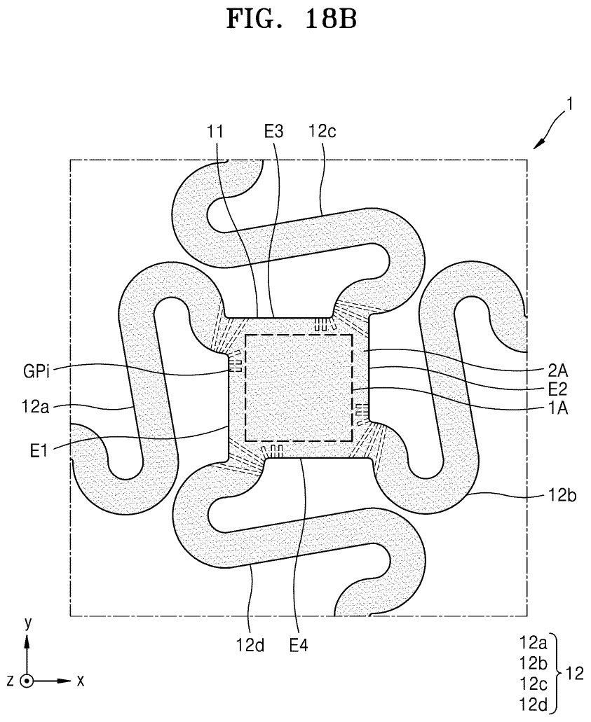

FIGS. 18A and 18B are each a plan view of a portion of the display device 1, according to an embodiment.

Referring to FIGS. 18A and 18B, an embodiment of the display device 1 may include the first island portion 11 and the plurality of first bridge portions 12. The first island portion 11 may include the first edge E1 and the second edge E2, which extend in the second direction (e.g., the y direction or the −y direction), and the third edge E3 and the fourth edge E4, which extend in the first direction (e.g., the x direction or the −x direction) and connecting the first edge E1 and the second edge E2.

The first island portion 11 may be connected to the plurality of first bridge portions 12. The first bridge portions 12 may include the 1-1 bridge portion 12a, the 1-2 bridge portion 12b, the 1-3 bridge portion 12c, and the 1-4 bridge portion 12d. The 1-1 bridge portion 12a may be connected to the first edge E1 of the first island portion 11, the 1-2 bridge portion 12b may be connected to the second edge E2 of the first island portion 11, the 1-3 bridge portion 12c may be connected to the third edge E3 of the first island portion 11, and the 1-4 bridge portion 12d may be connected to the fourth edge E4 of the first island portion 11.

In an embodiment, the first island portion 11 may include the first area 1A and the second area 2A outside the first area 1A. The first area 1A may be defined as an area where the barrier layer 103, the buffer layer 111, the inorganic insulating layer IIL, and the pixel driving circuit portions PC are arranged. An area from the edge of the first area 1A to the edge of the first island portion 11 may be defined as the second area 2A. The second area 2A may not include a layer including an inorganic insulating material that is easily cracked, unlike the first area 1A.

The second groove patterns GPi may be arranged in an area where the first island portion 11 and the first bridge portion 12 are connected to each other.

According to an embodiment, as shown in FIG. 18A, some (at least one) of the second groove patterns GPi may be arranged along an edge of each of the first bridge portions 12 at one side and an edge of the first island portion 11, connected to the edge of each of the first bridge portions 12 at one side, and the remainder of the second groove patterns GPi may be arranged along an edge of each of the first bridge portions 12 at the other side and an edge of the first island portion 11, connected to the edge of each of the first bridge portions 12 at the other side.

In an embodiment, for example, where edges of each of the first bridge portions 12 are referred to as a first edge and a second edge clockwise, in an area where the first island portion 11 and the 1-1 bridge portion 12a are connected to each other, some of the second groove patterns GPi may be arranged along a first edge of the 1-1 bridge portion 12a and the first edge E1 of the first island portion 11, connected to the first edge of the 1-1 bridge portion 12a, and some of the second groove patterns GPi may be arranged along a second edge of the 1-1 bridge portion 12a and the third edge E3 of the first island portion 11, connected to the second edge of the 1-1 bridge portion 12a. Similarly to the arrangement of the second groove patterns GPi in the area where the first island portion 11 and the 1-1 bridge portion 12a are connected to each other, the second groove patterns GPi may be arranged in each of an area where the first island portion 11 and the 1-2 bridge portion 12b are connected to each other, an area where the first island portion 11 and the 1-3 bridge portion 12c are connected to each other, and an area where the first island portion 11 and the 1-4 bridge portion 12d are connected to each other.

According to another embodiment, as shown in FIG. 18B, the second groove patterns GPi may be arranged in each of the areas where the first island portion 11 and the first bridge portion 12 are connected to each other. The second groove patterns GPi are arranged along the edge of each of the first bridge portions 12 at one side and the edge of the first island portion 11, connected to the edge of each of the first bridge portions 12 at one side, where some of the second groove patterns GPi may extend from the edge of the first bridge portion 12 at one side to the edge of the first bridge portion 12 at the other side or to the edge of the first island portion 11, connected to the edge of the first bridge portion 12 at the other side.

In an embodiment, for example, the second groove patterns GPi may be arranged along the first edge of the 1-1 bridge portion 12a and the first edge E1 of the first island portion 11 in the area where the first island portion 11 and the 1-1 bridge portion 12a are connected to each other. Some of the second groove patterns GPi may extend to the second edge of the 1-1 bridge portion 12a or the third edge E3 of the first island portion 11, connected to the second edge of the 1-1 bridge portion 12a, across the corner of the first island portion 11 or the 1-1 bridge portion 12a. Similarly to the arrangement of the second groove patterns GPi in the area where the first island portion 11 and the 1-1 bridge portion 12a are connected to each other, the second groove patterns GPi may be arranged in each of the area where the first island portion 11 and the 1-2 bridge portion 12b are connected to each other, the area where the first island portion 11 and the 1-3 bridge portion 12c are connected to each other, and the area where the first island portion 11 and the 1-4 bridge portion 12d are connected to each other.

In embodiments, as described above, the first groove pattern GP and/or the second groove pattern GPi may be arranged in the first island portion 11 and the first bridge portion 12, but the disclosure is not limited thereto. Shapes of the substrate 100 corresponding to the first island portion 11 and/or the substrate 100 corresponding to the first bridge portion 12 may be substantially the same as shapes of the substrate 100 corresponding to the second island portion 21 and/or the substrate 100 corresponding to the second bridge portion 22 described above with reference to FIG. 4, but the sizes and areas thereof may be different from each other. In an embodiment, for example, the first groove patterns GP and/or the second groove patterns GPi may also be arranged in the second island portion 21 and the second bridge portion 22 as described above.

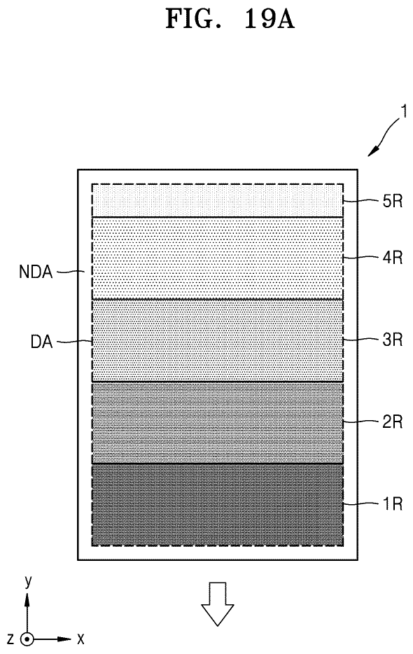

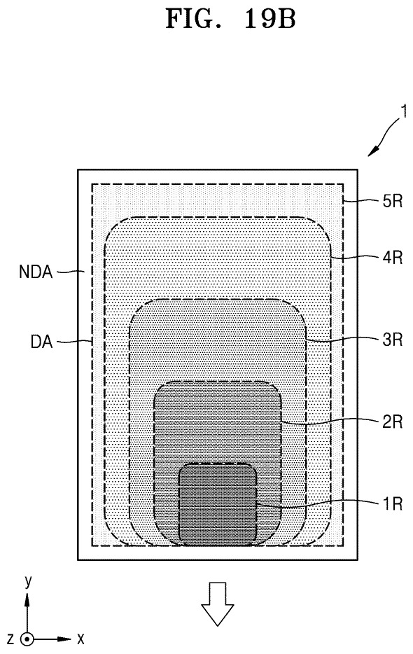

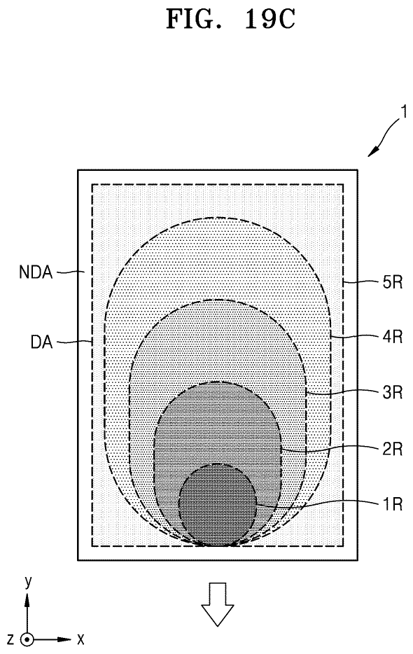

FIGS. 19A to 19C are each a plan view of the display device 1 according to an embodiment.

Referring to FIGS. 19A to 19C, an embodiment of the display device 1 may be stretched or reduced in the −y direction while one side of the display device 1 is fixed, according to external force applied by an external object or a user. The display device 1 may include the display area DA and the non-display area NDA. The display area DA and/or the non-display area NDA of the display device 1 may be stretched in the −y direction.

As described above with reference to FIG. 4, an embodiment of the display device 1 may include, in the display area DA, the first island portions 11 spaced apart from each other in the first direction (e.g., the x direction or the −x direction) and the second direction (e.g., the y direction or the −y direction) and the first bridge portions 12 connecting the adjacent first island portions 11 to each other, and include, in the non-display area NDA, for example, the first non-display area NDA1 shown in FIG. 4, the second island portions 21 spaced apart from each other in the first direction (e.g., the x direction or the −x direction) and the second direction (e.g., the y direction or the −y direction) and the second bridge portions 22 connecting the adjacent second island portions 21 to each other. Groove patterns opened in the −z direction may be arranged in the first island portions 11, the first bridge portions 12, the second island portions 21, and/or the second bridge portions 22.

An elongation rate of the display area DA may be the same as or greater than an elongation rate of the non-display area NDA. Accordingly, density of the groove patterns arranged in the first island portions 11 and the first bridge portions 12 may be the same as or greater than density of the groove patterns arranged in the second island portions 21 and the second bridge portions 22. Here, the density of the groove patterns of a certain area may be defined as a ratio of the total area occupied by the groove patterns in the certain area with respect to the entire area of the certain area. Here, the density of groove patterns may be adjusted by widths, lengths, intervals, and/or shapes of the groove patterns.

The third bridge portions 23 for connecting the display area DA and the first sub-non-display area SNDA1 to each other may be arranged in the second sub-non-display area SNDA2. One end portion of the third bridge portions 23 may be connected to the second island portion 21 and/or the second bridge portion 22, and the other end portion of the third bridge portions 23 may be connected to the first island portion 11 and/or the first bridge portion 12.

Due to a difference between the elongation rates of the display area DA and the non-display area NDA, stress may be concentrated on the second sub-non-display area SNDA2 shown in FIG. 4 when the display device 1 is contracted or stretched. Accordingly, groove patterns may not be arranged in the third bridge portions 23. Alternatively, the density of groove patterns arranged in the third bridge portions 23 may be relatively low compared to the density of groove patterns arranged in the first island portions 11 and the first bridge portions 12 and the density of groove patterns arranged in the second island portions 21 and the second bridge portions 22.

According to an embodiment, the display area DA may include a plurality of sub-areas having different elongation rates. In an embodiment, for example, in FIG. 19A, the display area DA includes a first sub-area 1R, a second sub-area 2R, a third sub-area 3R, a fourth sub-area 4R, and a fifth sub-area 5R, but the disclosure is not limited thereto. The display area DA may include more or fewer sub-areas having different elongation rates. The first sub-area 1R, the second sub-area 2R, the third sub-area 3R, and fourth sub-area 4R, and the fifth sub-area 5R may be sequentially arranged in the y direction. Here, a groove pattern of an A area denotes groove patterns arranged in an island portion and/or a bridge portion included in the A area.

Each of the first sub-area 1R, the second sub-area 2R, the third sub-area 3R, the fourth sub-area 4R, and the fifth sub-area 5R may have a rectangular shape elongated in the first direction (e.g., the x direction or the −x direction), extending from a left edge (−x direction) of the display area DA to a right edge (+x direction) of the display area DA. The widths of the first sub-area 1R, the second sub-area 2R, the third sub-area 3R, the fourth sub-area 4R, and the fifth sub-area 5R in the second direction (e.g., the y direction or the −y direction) may be the same as or different from each other. In an embodiment, for example, the width of the fifth sub-area 5R in the second direction (e.g., the y direction or the −y direction) arranged at the fixed side of the display device 1 may be less than the widths of other sub-areas (the first to fourth sub-areas 1R to 4R) in the second direction (e.g., the y direction or the −y direction).

According to an embodiment, as shown in FIGS. 19B and 19C, the display area DA includes a plurality of sub-areas, and the sub-areas may be arranged to be in contact with a lower edge (−y direction) of the display area DA. The first sub-area 1R, the second sub-area 2R, the third sub-area 3R, and the fourth sub-area 4R may be spaced apart from the left edge (−x direction), the right edge (+x direction), and an upper edge (+y direction) of the display area DA. The second sub-area 2R may be arranged outside the first sub-area 1R, the third sub-area 3R may be arranged outside the second sub-area 2R, and the fourth sub-area 4R may be arranged outside the third sub-area 3R. The fifth sub-area 5R may be the remaining display area DA outside the fourth sub-area 4R.

According to an embodiment, as shown in FIG. 19B, the first sub-area 1R, the second sub-area 2R, the third sub-area 3R, and the fourth sub-area 4R may have quadrangular shapes having rounded corners. According to another embodiment, as shown in FIG. 19C, the first sub-area 1R, the second sub-area 2R, the third sub-area 3R, and the fourth sub-area 4R may have circular or oval shapes. The fifth sub-area 5R may be an outer area of the fourth sub-area 4R.

The first sub-area 1R, the second sub-area 2R, the third sub-area 3R, the fourth sub-area 4R, and the fifth sub-area 5R may have different elongation rates from each other. In other words, densities of groove patterns of the first sub-area 1R, the second sub-area 2R, the third sub-area 3R, the fourth sub-area 4R, and the fifth sub-area 5R may be different from each other.

According to an embodiment, the densities of the groove patterns of the first sub-area 1R, the second sub-area 2R, the third sub-area 3R, the fourth sub-area 4R, and the fifth sub-area 5R may be changed stepwise such that the density of the groove pattern of the first sub-area 1R is the greatest and the density of the groove pattern of the fifth sub-area 5R is the lowest. In other words, the density of the groove pattern of the first sub-area 1R may be greater than the density of the groove pattern of the second sub-area 2R, the density of the groove pattern of the second sub-area 2R may be greater than the density of the groove pattern of the third sub-area 3R, the density of the groove pattern of the third sub-area 3R may be greater than the density of the groove pattern of the fourth sub-area 4R, and the density of the groove pattern of the fourth sub-area 4R may be greater than the density of the groove pattern of the fifth sub-area 5R.

According to another embodiment, the densities of the groove patterns of the first sub-area 1R, the second sub-area 2R, the third sub-area 3R, the fourth sub-area 4R, and the fifth sub-area 5R may be changed stepwise such that the density of the groove pattern of the first sub-area 1R is the lowest and the density of the groove pattern of the fifth sub-area 5R is the greatest.

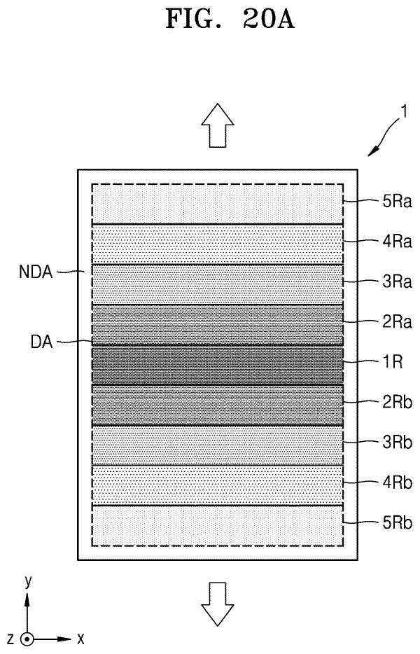

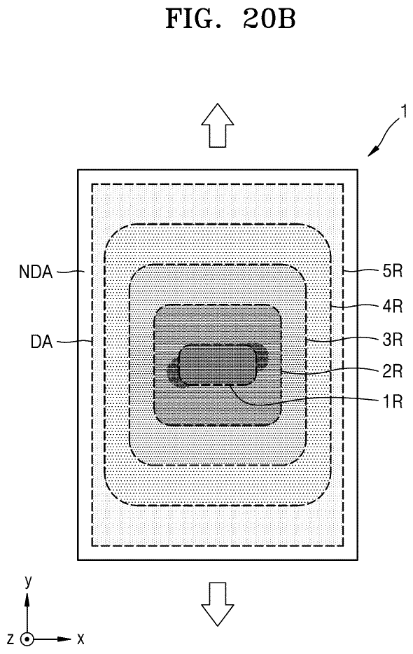

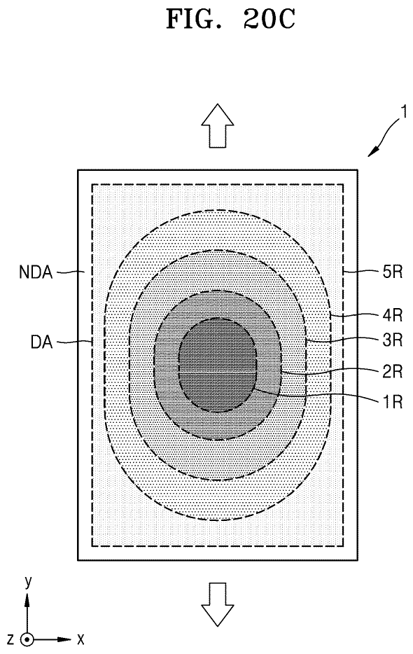

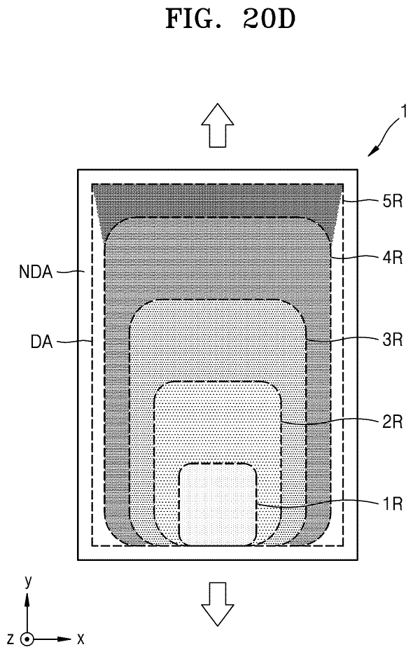

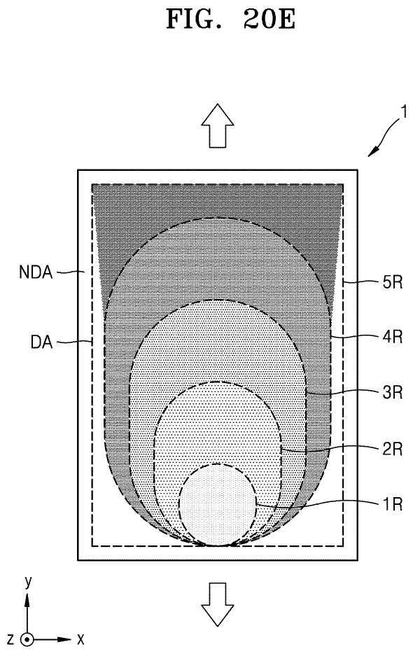

FIGS. 20A to 20E are each a plan view of the display device 1 according to an embodiment.

Referring to FIGS. 20A to 20E, the display device 1 may be stretched in the second direction (e.g., the y direction and/or the −y direction) by external force applied by an external object or a part of body of a person. The display area DA and/or the non-display area NDA of the display device 1 may be stretched in the ±y direction.

The display area DA may include the plurality of sub-areas having different elongation rates from each other. According to an embodiment, as shown in FIG. 20A, the display area DA may include the first sub-area 1R, a first second sub-area (hereinafter will be referred to as “2-1 sub-area”) 2Ra, a second second sub-area (hereinafter will be referred to as “2-2 sub-area”) 2Rb, a first third sub-area (hereinafter will be referred to as “3-1 sub-area”) 3Ra, a second third sub-area (hereinafter will be referred to as “3-2 sub-area”) 3Rb, a first fourth sub-area (hereinafter will be referred to as “4-1 sub-area”) 4Ra, a second fourth sub-area (hereinafter will be referred to as “4-2 sub-area”) 4Rb, a first fifth sub-area (hereinafter will be referred to as “5-1 sub-area”) 5Ra, and a second fifth sub-area (hereinafter will be referred to as “5-2 sub-area”) 5Rb. Based on the first sub-area 1R, the 2-1 sub-area 2Ra, the 3-1 sub-area 3Ra, the 4-1 sub-area 4Ra, and the 5-1 sub-area 5Ra may be sequentially arranged in the +y direction, and based on the first sub-area 1R, the 2-2 sub-area 2Rb, the 3-2 sub-area 3Rb, the 4-2 sub-area 4Rb, and the 5-2 sub-area 5Rb may be sequentially arranged in the −y direction.

Each of the first sub-area 1R, the 2-1 sub-area 2Ra, the 2-2 sub-area 2Rb, the 3-1 sub-area 3Ra, the 3-2 sub-area 3Rb, the 4-1 sub-area 4Ra, the 4-2 sub-area 4Rb, the 5-1 sub-area 5Ra, and the 5-2 sub-area 5Rb may have a rectangular shape elongated in the first direction (e.g., the x direction or the −x direction), extending from the left edge (−x direction) of the display area DA to the right edge (+x direction) of the display area DA.

Sub-areas arranged symmetrically based on the first sub-area 1R may have a same elongation rate as each other. In other words, the sub-areas arranged symmetrically based on the first sub-area 1R may have a same density of groove patterns. In an embodiment, for example, the density of the groove pattern of the 2-1 sub-area 2Ra may be the same as the density of the groove pattern of the 2-2 sub-area 2Rb, the density of the groove pattern of the 3-1 sub-area 3Ra may be the same as the density of the groove pattern of the 3-2 sub-area 3Rb, the density of the groove pattern of the 4-1 sub-area 4Ra may be the same as the density of the groove pattern of the 4-2 sub-area 4Rb, and the density of the groove pattern of the 5-1 sub-area 5Ra may be the same as the density of the groove pattern of the 5-2 sub-area 5Rb.

According to an embodiment, the densities of the groove patterns of the sub-areas may change stepwise such that the density of the groove pattern of the first sub-area 1R located at the center of the display area DA is the greatest and the densities of the groove patterns of the 5-1 sub-area 5Ra and the 5-2 sub-area 5Rb located outer side of the display area DA are the lowest.

According to another embodiment, the densities of the groove patterns of the sub-areas may change stepwise such that the density of the groove pattern of the first sub-area 1R located at the center of the display area DA is the lowest and the densities of the groove patterns of the 5-1 sub-area 5Ra and the 5-2 sub-area 5Rb located outer side of the display area DA are the greatest.

According to an embodiment, as shown in FIGS. 20B and 20C, the display area DA includes the plurality of sub-areas, and centers of the sub-areas may be arranged to overlap the center of the display area DA. Here, the center of each sub-area may be an intersection point where an imaginary straight line bisecting the corresponding sub-area in the first direction (e.g., the x direction or the −x direction) and an imaginary straight line bisecting the corresponding sub-area in the second direction (e.g., the y direction or the −y direction) meet each other. The first sub-area 1R may overlap the center of the display area DA. The second sub-area 2R may be arranged outside the first sub-area 1R, the third sub-area 3R may be arranged outside the second sub-area 2R, the fourth sub-area 4R may be arranged outside the third sub-area 3R, and the fifth sub-area 5R may be arranged outside the fourth sub-area 4R. Each of the second sub-area 2R, the third sub-area 3R, the fourth sub-area 4R, and the fifth sub-area 5R may have a type of frame shape extending along an edge of a sub-area at an inner side.

According to an embodiment, as shown in FIG. 20B, the first sub-area 1R, the second sub-area 2R, the third sub-area 3R, and the fourth sub-area 4R may have quadrangular shapes having rounded corners. According to another embodiment, as shown in FIG. 20C, the first sub-area 1R, the second sub-area 2R, the third sub-area 3R, and the fourth sub-area 4R may have circular or oval shapes.

According to an embodiment, as shown in FIGS. 20D and 20E, the display area DA includes the plurality of sub-areas, and the sub-areas may be arranged to be in contact with the lower edge (−y direction) of the display area DA. The first sub-area 1R, the second sub-area 2R, the third sub-area 3R, and the fourth sub-area 4R may be spaced apart from the left edge (−x direction), the right edge (+x direction), and the upper edge (+y direction) of the display area DA. The second sub-area 2R may be arranged outside the first sub-area 1R, the third sub-area 3R may be arranged outside the second sub-area 2R, the fourth sub-area 4R may be arranged outside the third sub-area 3R, and the fifth sub-area 5R may be arranged outside the fourth sub-area 4R. A left edge (−x direction), a right edge (+x direction), and an upper edge (+y direction) of the fifth sub-area 5R may match the left edge (−x direction), the right edge (+x direction), and the upper edge (+y direction) of the display area DA.

According to an embodiment, as shown in FIG. 20D, the first sub-area 1R, the second sub-area 2R, the third sub-area 3R, and the fourth sub-area 4R may have quadrangular shapes having rounded corners. According to another embodiment, as shown in FIG. 20E, the first sub-area 1R, the second sub-area 2R, the third sub-area 3R, and the fourth sub-area 4R may have circular or oval shapes. The fifth sub-area 5R may be an outer area of the fourth sub-area 4R.

In an embodiment, as described above, the first sub-area 1R, the second sub-area 2R, the third sub-area 3R, the fourth sub-area 4R, and the fifth sub-area 5R may have different elongation rates from each other. In other words, the densities of the groove patterns of the first sub-area 1R, the second sub-area 2R, the third sub-area 3R, the fourth sub-area 4R, and the fifth sub-area 5R may be different from each other.

According to an embodiment, the densities of the groove patterns of the first sub-area 1R, the second sub-area 2R, the third sub-area 3R, the fourth sub-area 4R, and the fifth sub-area 5R may be changed stepwise such that the density of the groove pattern of the first sub-area 1R is the greatest and the density of the groove pattern of the fifth sub-area 5R is the lowest. According to another embodiment, the densities of the groove patterns of the first sub-area 1R, the second sub-area 2R, the third sub-area 3R, the fourth sub-area 4R, and the fifth sub-area 5R may be changed stepwise such that the density of the groove pattern of the first sub-area 1R is the lowest and the density of the groove pattern of the fifth sub-area 5R is the greatest.

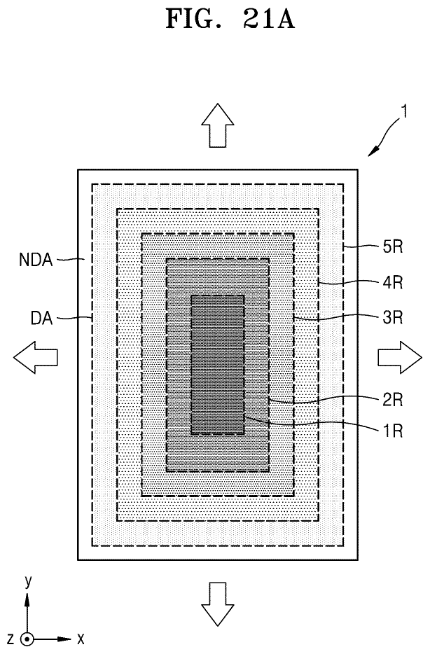

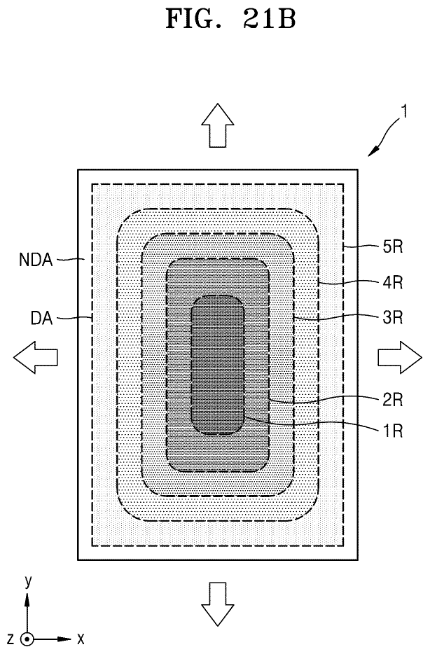

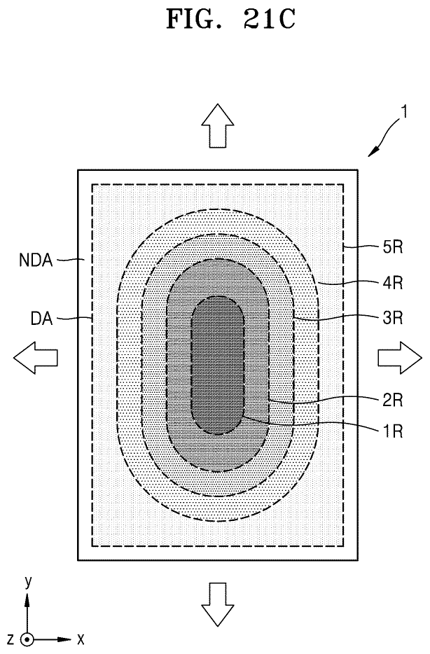

FIGS. 21A to 21C are each a plan view of the display device 1 according to an embodiment.

Referring to FIGS. 21A to 21C, an embodiment of the display device 1 may be stretched in a plurality of directions, for example, the first direction (e.g., the x direction and/or the −x direction) and the second direction (e.g., the y direction and/or the −y direction), by external force applied by an external object or a part of body of a person. The display area DA and/or the non-display area NDA of the display device 1 may be stretched in the ±x direction and the ±y direction.

The display area DA may include the plurality of sub-areas and the centers of the sub-areas may overlap the center of the display area DA. Here, the center of each sub-area may be an intersection point where an imaginary straight line bisecting the corresponding sub-area in the first direction (e.g., the x direction or the −x direction) and an imaginary straight line bisecting the corresponding sub-area in the second direction (e.g., the y direction or the −y direction) meet each other. The first sub-area 1R may overlap the center of the display area DA. The second sub-area 2R may be arranged outside the first sub-area 1R, the third sub-area 3R may be arranged outside the second sub-area 2R, the fourth sub-area 4R may be arranged outside the third sub-area 3R, and the fifth sub-area 5R may be arranged outside the fourth sub-area 4R. Each of the second sub-area 2R, the third sub-area 3R, the fourth sub-area 4R, and the fifth sub-area 5R may have a type of frame shape extending along an edge of a sub-area at an inner side.

According to an embodiment, as shown in FIG. 21A, the first sub-area 1R, the second sub-area 2R, the third sub-area 3R, and the fourth sub-area 4R may have quadrangular shapes. According to another embodiment, as shown in FIG. 21B, the first sub-area 1R, the second sub-area 2R, the third sub-area 3R, and the fourth sub-area 4R may have quadrangular shapes having rounded corners. According to another embodiment, as shown in FIG. 21C, the first sub-area 1R, the second sub-area 2R, the third sub-area 3R, and the fourth sub-area 4R may have circular or oval shapes.

In an embodiment, as described above, the first sub-area 1R, the second sub-area 2R, the third sub-area 3R, the fourth sub-area 4R, and the fifth sub-area 5R may have different elongation rates from each other. In other words, the densities of the groove patterns of the first sub-area 1R, the second sub-area 2R, the third sub-area 3R, the fourth sub-area 4R, and the fifth sub-area 5R may be different from each other.

According to an embodiment, the densities of the groove patterns of the first sub-area 1R, the second sub-area 2R, the third sub-area 3R, the fourth sub-area 4R, and the fifth sub-area 5R may be changed stepwise such that the density of the groove pattern of the first sub-area 1R is the greatest and the density of the groove pattern of the fifth sub-area 5R is the lowest. According to another embodiment, the densities of the groove patterns of the first sub-area 1R, the second sub-area 2R, the third sub-area 3R, the fourth sub-area 4R, and the fifth sub-area 5R may be changed stepwise such that the density of the groove pattern of the first sub-area 1R is the lowest and the density of the groove pattern of the fifth sub-area 5R is the greatest.

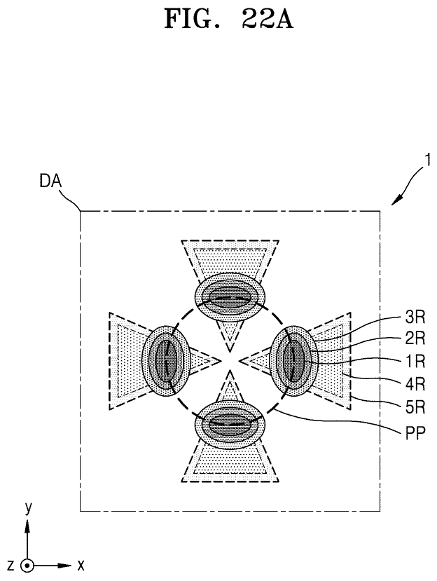

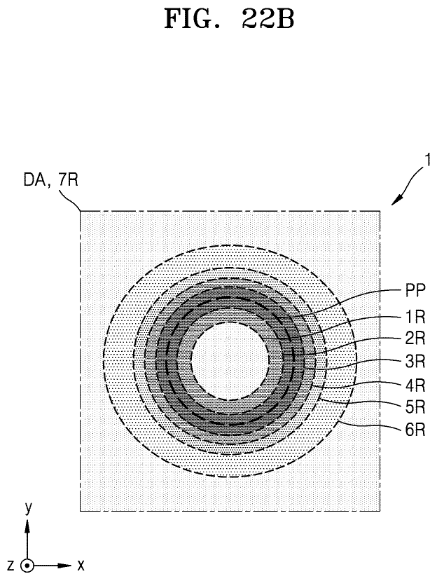

FIGS. 22A and 22B are each a plan view of the display device 1 according to an embodiment.

The display device 1 may be stretched in the third direction (e.g., the z direction or the −z direction) by external force applied by an external object or a part of body of a person. According to an embodiment, in FIGS. 22A and 22B, a portion of the display device 1, for example, a partial area of the display area DA, protrudes in the z direction along a surface of a hemisphere PP.

Referring to FIG. 22A, in an embodiment, the display area DA may include a plurality of sub-areas having different elongation rates from each other. In an embodiment, for example, as shown in FIG. 22A, the display area DA may include the first sub-areas 1R, the second sub-areas 2R, the third sub-areas 3R, the fourth sub-areas 4R, the fifth sub-areas 5R, and a sixth sub-area 6R.

According to an embodiment, the first sub-areas 1R may overlap an edge of the hemisphere PP. According to an embodiment, each of the first sub-areas 1R may be arranged upward (y direction), downward (−y direction), left (−x direction), and right (x direction), based on a center of the hemisphere PP.

Each of the second sub-areas 2R may be arranged outside the first sub-area 1R to surround the first sub-area 1R. Each of the third sub-areas 3R may be arranged outside the second sub-area 2R to surround the second sub-area 2R. In a plan view, the first sub-area 1R may have a circle or oval shape. Each of the second sub-areas 2R and third sub-areas 3R may have a type of frame shape extending along an edge of a sub-area at an inner side.

Each of the fourth sub-areas 4R may have an approximately triangular shape that is arranged outside the third sub-area 3R while one vertex thereof faces the center of the hemisphere PP. Each of the fifth sub-areas 5R may have an approximately triangular shape that is arranged outside the third sub-area 3R and the fourth sub-area 4R while one vertex thereof faces the center of the hemisphere PP. The sixth sub-area 6R may be the display area DA outside the first sub-area 1R to the fifth sub-area 5R.

Here, a sub-area closer to the edge of the hemisphere PP, where stress is concentrated, may have a greater elongation rate. In other words, a sub-area closer to the edge of the hemisphere PP may have a greater density of groove patterns. In an embodiment, for example, the densities of the groove patterns of the sub-areas may be changed stepwise such that, among the first sub-area 1R, the second sub-area 2R, the third sub-area 3R, the fourth sub-area 4R, and the fifth sub-area 5R, the density of the groove pattern of the first sub-area 1R is the greatest and the density of the groove pattern of the fifth sub-area 5R is the lowest. The density of the groove pattern of the sixth sub-area 6R may be less than the density of the groove pattern of the fifth sub-area 5R.

According to an embodiment, as shown in FIG. 22B, the display area DA may include first to seventh sub-areas 1R to 7R. In a plan view, the center of each of the first to sixth sub-areas 1R to 6R may match the center of the hemisphere PP. In a plan view the first sub-area 1R may have a circular shape having a same center as the hemisphere PP. The second sub-area 2R may be arranged outside the first sub-area 1R, the third sub-area 3R may be arranged outside the second sub-area 2R, the fourth sub-area 4R may be arranged outside the third sub-area 3R, the fifth sub-area 5R may be arranged outside the fourth sub-area 4R, and the sixth sub-area 6R may be arranged outside the fifth sub-area 5R. Each of the second sub-area 2R, the third sub-area 3R, the fourth sub-area 4R, the fifth sub-area 5R, and the sixth sub-area 6R may have a type of frame shape extending along an edge of a sub-area at an inner side. The seventh sub-area 7R may be the display area DA outside the sixth sub-area 6R.

Here, a sub-area closer to the edge of the hemisphere PP, where stress is concentrated, may have a greater elongation rate. In an embodiment, for example, the density of the groove pattern of the third sub-area 3R overlapping the edge of the hemisphere PP may be the greatest. The density of the groove pattern of the second sub-area 2R may be less than the density of the groove pattern of the third sub-area 3R, but may be greater than the density of the groove pattern of the first sub-area 1R. The density of the groove pattern of the fourth sub-area 4R may be less than the density of the groove pattern of the third sub-area 3R, but may be greater than the density of the groove pattern of the fifth sub-area 5R. The density of the groove pattern of the fifth sub-area 5R may be greater than the density of the groove pattern of the sixth sub-area 6R. The density of the groove pattern of the seventh sub-area 7R may be less than the density of the groove pattern of the sixth sub-area 6R.

Stress of the display device 1 may be distributed and an elongation rate thereof may be increased by arranging the sub-areas having different densities of groove patterns along a stretching direction of the display device 1. In embodiments, the number of sub-areas having different elongation rate may vary.

The display device 1 according to the above-described embodiments may be used for various electronic device capable of providing an image. Here, an electronic device denotes a device capable of providing a certain image by using electricity.

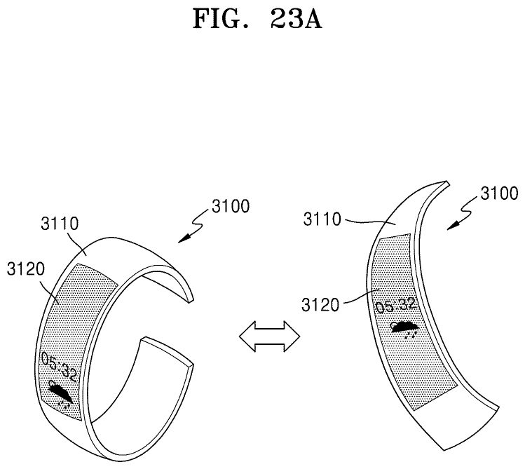

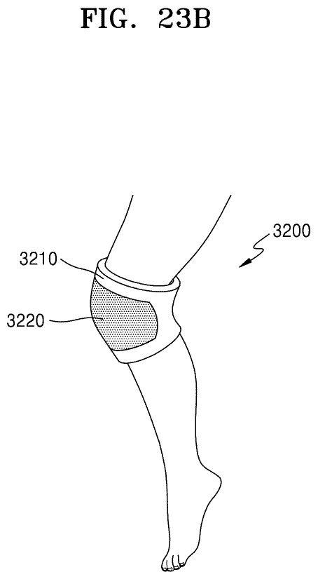

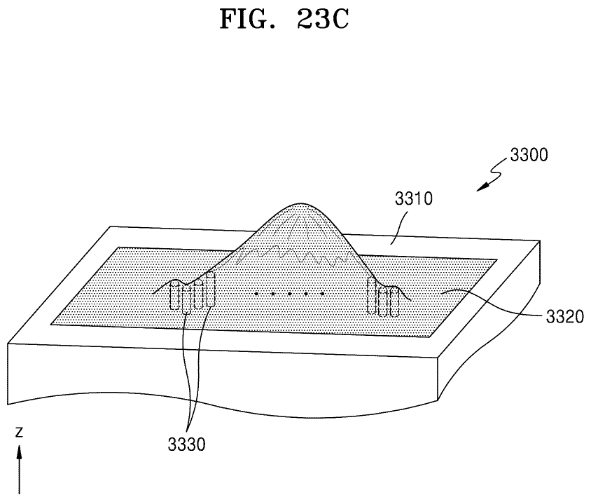

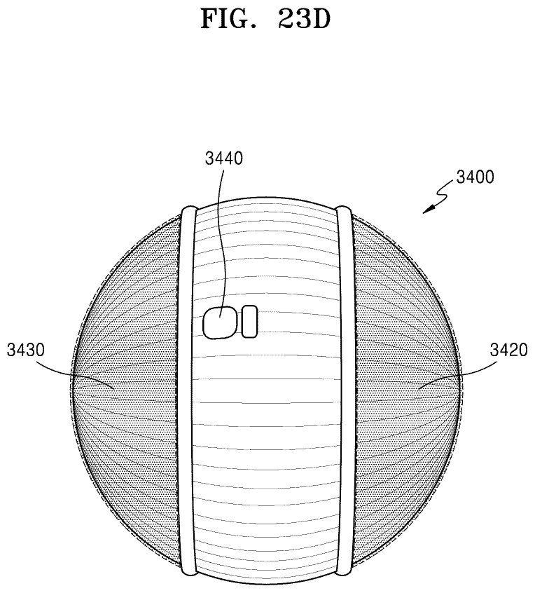

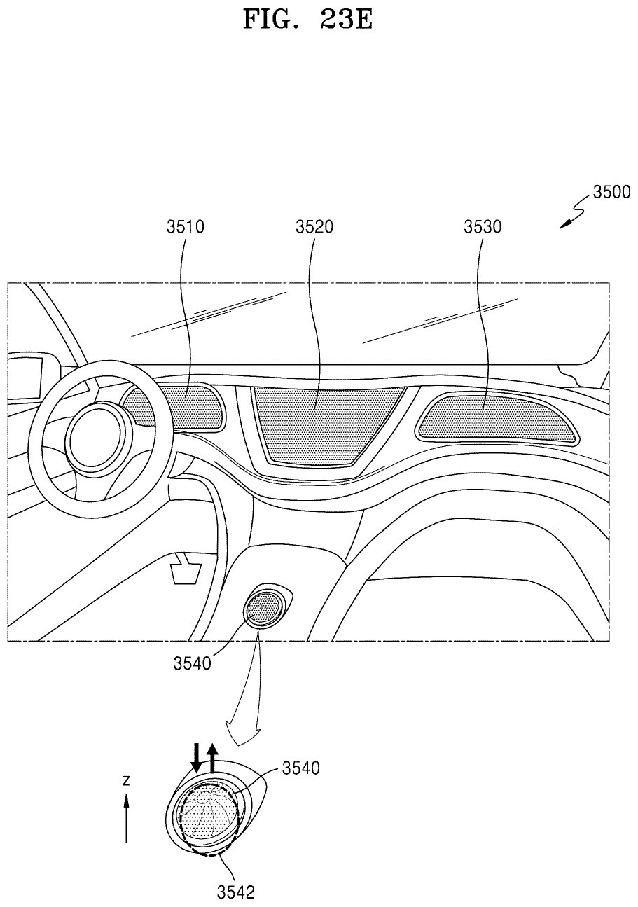

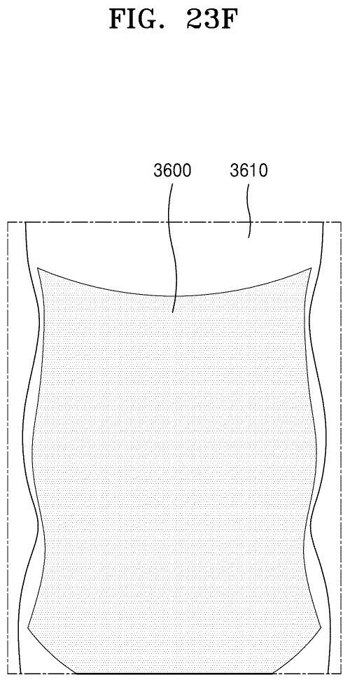

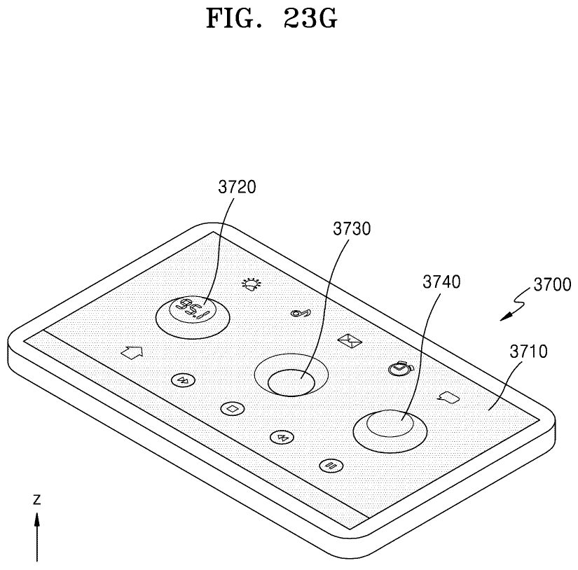

FIGS. 23A to 23G are each a perspective view of an example of an electronic device including a display device, according to an embodiment.

Referring to FIG. 23A, a display device according to an embodiment may be used for a wearable electronic device 3100 that may be worn on a part of a body of a user. The wearable electronic device 3100 may include a body portion 3110 and a display portion 3120 provided in the body portion 3110. The display device according to embodiments may be used as the display portion 3120 of the wearable electronic device 3100. The wearable electronic device 3100 of FIG. 23A may be transformed. According to an embodiment, the wearable electronic device 3100 may be used as a smart watch or a smart phone according to the user's choice.

FIG. 23B illustrates an embodiment where the electronic device is a medical electronic device 3200. According to an embodiment, the medical electronic device 3200 may include a body portion 3210 and a light-emitting portion 3220. The display device according to embodiments may be used as the light-emitting portion 3220 of the medical electronic device 3200. The light-emitting portion 3220 may emit, to a body of a patient, light of a uniform wavelength band (e.g., infrared light, visible light, or the like). According to an embodiment, the body portion 3210 may include an elastic fiber material and have a structure capable of being worn on a body of a user.

FIG. 23C illustrates an embodiment where the electronic device is an educational electronic device 3300. According to an embodiment, the educational electronic device 3300 may include a display portion 3320 provided in a frame 3310. The display portion 3320 may use a display device according to embodiments. An image of the sea with waves, a mountain covered with snow, or a volcano with lava may be provided through the display portion 3320, and at this time, the display portion 3320 may be stretched in a height direction (e.g., a z direction) by reflecting the height of waves, mountain, or volcano. According to some embodiments, a portion of the display portion 3320 may 3-dimensionally display movement of the lava as a height thereof sequentially changes in a direction the lava flows. The educational electronic device 3300 may include a plurality pins 3330 (or stroke portions) arranged on a rear surface of the display portion 3320 such that the display portion 3320 is stretched in the height direction. An image displayed on the display portion 3320 may be 3-dimensionally realized to have heights as the pins 3330 move in the third direction (e.g., the z direction or the −z direction). FIG. 23C shows an embodiment where the electronic device is the educational electronic device 3300, but the purpose thereof is not limited as long as information about a certain image is provided. Electronic devices shown in FIGS. 23A to 23C have variable shapes, but the disclosure is not limited thereto. In embodiments, as described below, a display device according to embodiments may be used for an electronic device in which a portion representing an image (e.g., a screen) is fixed.

FIG. 23D illustrates a robot 3400 as an electronic device according to an embodiment. The robot 3400 may recognize movement or an object by using a camera portion 3440 and display a specific image to a user through display portions 3420 and 3430. According to some embodiments, display devices according to an embodiment may be stretched in various directions as described above, and thus may be assembled to a body frame having a hemispherical shape, and accordingly, the robot 3400 may include hemispherical display portions 3420 and 3430.

FIG. 23E illustrates a vehicle display device 3500 as an electronic device according to an embodiment. The vehicle display device 3500 may include a cluster 3510, a center information display (CID) 3520, and/or a passenger display 3530. A display device according to an embodiment is stretchable in various directions, and thus may be used for the cluster 3510, the CID 3520, and/or the passenger display 3530 without being restricted by a shape of an internal frame of a vehicle.

FIG. 23E illustrates an embodiment where the cluster 3510, the CID 3520, and/or the passenger display 3530 are separated from each other, but the disclosure is not limited thereto. According to another embodiment, two or more of the cluster 3510, the CID 3520, and the passenger display 3530 may be integrated with each other.

According to some embodiments, the vehicle display device 3500 may include a button 3540 for representing a specific image. Referring to an enlarged view of FIG. 23E, the hemispherical button 3540 may include an object 3542 providing a feeling of using a button while moving in the z direction or the −z direction, and a display device arranged on the object 3542. According to some embodiments, where the object 3542 has a 3-dimensionally rounded surface, the display device may also have the 3-dimensionally rounded surface.

FIG. 23F illustrates an embodiment where an electronic device is an advertising or exhibitory electronic device 3600. According to some embodiments, the advertising or exhibitory electronic device 3600 may be installed at a fixed structure 3610, such as a wall or a pillar. When the structure 3610 includes an uneven surface as shown in FIG. 23F, the advertising or exhibitory electronic device 3600 may also be arranged along the uneven surface of the structure 3610. According to some embodiments, the advertising or exhibitory electronic device 3600 may be installed at the structure 3610 by using a thermal contraction film or the like.

FIG. 23G illustrates a controller 3700 as an electronic device according to an embodiment. The controller 3700 may include an image type button. In an embodiment, for example, the controller 3700 may include first to third button areas 3720 to 3740 provided as a partial area of a display portion 3710 protrudes in a z direction or protrudes in a −z direction (or sunken in the z direction). According to some embodiments, the first and third button areas 3720 and 3740 may protrude in the z direction, and the second button 3730 may protrude in the −z direction (or sunken in the z direction).

According to an embodiment, a display device, which is stretchable in various directions and in which damage caused by concentration of stress may be prevented, may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a first surface and a second surface, which are opposite to each other, wherein the substrate includes island areas and bridge areas connecting neighboring island areas to each other and having serpentine shapes; and
wires arranged on the first surface of the bridge areas,
wherein groove patterns are defined in each of the bridge areas to be opened in a direction of the second surface.

2. The display device of claim 1, wherein each of the bridge areas comprises:
two round portions; and
a straight portion between the two round portions.

3. The display device of claim 2, wherein each of the two round portions comprises an inner edge and an outer edge, and
the groove patterns are arranged along the inner edge.

4. The display device of claim 2, wherein each of the two round portions comprises an inner edge and an outer edge, and
the groove patterns are arranged along the outer edge.

5. The display device of claim 2, wherein each of the two round portions comprises an inner edge and an outer edge,
at least one of the groove patterns are arranged along the inner edge, and
a remainder of the groove patterns are arranged along the outer edge.

6. The display device of claim 5, wherein the at least one of the groove patterns arranged along the inner edge and the remainder of the groove patterns arranged along the outer edge are misaligned with each other.

7. The display device of claim 2, wherein each of the bridge areas comprises a first edge and a second edge, and
each of the groove patterns extends from the first edge of the bridge area to the second edge of the bridge area.

8. The display device of claim 7, wherein a width of each of the bridge areas and a width of each of the groove patterns in a direction perpendicular to an extension direction of each of the bridge areas are the same as each other.

9. The display device of claim 2, wherein the groove patterns are arranged in the two round portions and the straight portion, and
an interval between the groove patterns arranged in the two round portions is smaller than an interval between the groove patterns arranged in the straight portion.

10. The display device of claim 2, wherein the plurality of groove patterns are arranged in the two round portions and the straight portion, and
a width of each of the groove patterns arranged in the two round portions in an extension direction of each of the bridge areas is greater than a width of each of the groove patterns arranged in the straight portion in the extension direction of each of the bridge areas.

11. The display device of claim 1, wherein the substrate comprises a first base layer and a second base layer on the first base layer, and
the groove patterns are defined by an opening defined through the first base layer.

12. The display device of claim 1, wherein the substrate comprises a first base layer and a second base layer on the first base layer, and
the groove patterns are defined by an opening defined through the first base layer and the second base layer.

13. The display device of claim 1, wherein each of the bridge areas comprises a first area overlapping the wires and a second area outside the first area, and
the groove patterns are arranged in the second area.

14. The display device of claim 1, wherein a width of each of the groove patterns in an extension direction of each of the bridge areas increases towards an edge of each of the bridge areas.

15. The display device of claim 1, wherein a width of each of the groove patterns in an extension direction of each of the bridge areas decreases towards an edge of each of the bridge areas.

16. The display device of claim 1, wherein each of the groove patterns has a rounded edge along an arc of an imaginary circle or an imaginary oval, in a plan view.

17. A display device comprising:
a substrate including a first surface and a second surface, which are opposite to each other, wherein the substrate includes island areas and bridge areas connecting neighboring island areas to each other and having serpentine shapes; and
wires arranged on the first surface of each of the bridge areas,
wherein groove patterns are defined in a portion of the island areas adjacent to the bridge areas and in a portion of the bridge areas adjacent to the island areas to be opened in a direction of the second surface.

18. The display device of claim 17, wherein each of the bridge areas comprises a first edge and a second edge, and
the groove patterns are arranged along the first edge and an edge of island area connected to the first edge.

19. The display device of claim 17, wherein each of the bridge areas comprises a first edge and a second edge,
at least one of the groove patterns are arranged along the first edge and an edge of island area connected to the first edge, and
a remainder of the groove patterns are arranged along the second edge and an edge of island area connected to the second edge.

20. The display device of claim 17, wherein each of the bridge areas comprises a first edge and a second edge, and
the groove patterns are arranged along the first edge and an edge of island area connected to the first edge, wherein at least one of the groove patterns extends from the first edge to the second edge or to an edge of the island area connected to the second edge.

21. A display device in which a display area and a non-display area outside the display area are defined, the display device comprising:
a substrate including a first surface and a second surface, which are opposite to each other, wherein the substrate includes island areas and bridge areas connecting neighboring island areas to each other and having serpentine shapes; and
wires arranged on the first surface of the bridge areas,
wherein groove patterns are defined in the substrate to be opened in a direction of the second surface,
wherein the display area includes sub-areas having different elongation rates from each other.

22. The display device of claim 21, wherein densities of the groove patterns of each of the sub-areas are different from each other.

23. The display device of claim 22, wherein the sub-areas comprise a first sub-area, a second sub-area outside the first sub-area, and a third sub-area outside the second sub-area, and
a density of the groove patterns of the first sub-area is greater than a density of the groove patterns of the second sub-area, and the density of the groove patterns of the second sub-area is greater than a density of the groove patterns of the third sub-area.

24. The display device of claim 22, wherein the sub-areas comprise a first sub-area, a second sub-area outside the first sub-area, and a third sub-area outside the second sub-area, and
a density of the groove patterns of the first sub-area is less than a density of the groove patterns of the second sub-area, and the density of the groove patterns of the second sub-area is less than a density of the groove patterns of the third sub-area.

25. The display device of claim 22, wherein the sub-areas comprise a first sub-area, a second sub-area outside the first sub-area, and a third sub-area outside the second sub-area, and
a density of the groove patterns of the second sub-area is greater than a density of the groove patterns of the first sub-area and a density of the groove patterns of the third sub-area.
